(19) United States
(12) Patent Application Publication
(10) Pub. No.: US 2011/0244396 A1
(43) Pub. Date: Oct. 6, 2011

(54) EXPOSURE APPARATUS, EXCHANGE METHOD OF OBJECT, EXPOSURE METHOD, AND DEVICE MANUFACTURING METHOD

(75) Inventor: Yasuo AOKI, Zushi-shi (JP)

(73) Assignee: NIKON CORPORATION, TOKYO (JP)

(21) Appl. No.: 13/042,931

(22) Filed: Mar. 8, 2011

Related U.S. Application Data
(60) Provisional application No. 61/319,976, filed on Apr. 1, 2010.
(60) Provisional application No. 61/319,917, filed on Apr. 1, 2010.

(51) Int. Cl. G03F 7/20; G03B 27/58; B65G 49/00

(52) U.S. Cl. 430/319; 355/72; 430/325; 430/322; 414/800

(57) ABSTRACT

A first carrier unit carries out a substrate tray that supports a substrate from below from a substrate holder by sliding the substrate tray in one axis direction (Y-axis direction) parallel to the substrate surface. Meanwhile, a second carrier unit carries in a substrate tray that supports a substrate subject to carry-in from below onto the substrate holder by sliding the substrate tray in the Y-axis direction, in parallel with the carry-out operation of the substrate (in a state where a part of the substrate tray that supports the substrate subject to carry-out is located on the substrate holder). Consequently, exchange of the substrate on the substrate holder can speedily be performed.

### CROSS-REFERENCE TO RELATED APPLICATIONS

This non-provisional application claims the benefit of Provisional Application No. 61/319,917 filed Apr. 1, 2010 and Provisional Application No. 61/319,976 filed Apr. 1, 2010, the disclosures of which are hereby incorporated herein by reference in their entirety.

### BACKGROUND OF THE INVENTION

1. Field of the Invention

The present invention relates to exposure apparatuses, exchange methods of objects, exposure methods and device manufacturing methods, and more particularly to an exposure apparatus that consecutively exposes a plurality of substrates with an energy beam, an exchange method of an object of exchanging an object held on a holding device for another object, an exposure method making use of the exchange method, and a device manufacturing method using the exposure apparatus or the exposure method.

2. Description of the Background Art

Conventionally, in a lithography process for manufacturing electron devices (microdevices) such as liquid crystal display elements or semiconductor devices (integrated circuits or the like), an exposure apparatus is used such as a scanning-type projection exposure apparatus that, while synchronously moving a mask or a reticle (hereinafter, generically referred to as a “mask”) and an object such as a glass plate or a wafer (hereinafter, generically referred to as a “substrate”) along a predetermined scanning direction (scan direction), transfers a pattern formed on the mask onto the substrate via a projection optical system (refer to, for example, U.S. Patent Application Publication No. 2010/0018950).

In this type of the exposure apparatus, the substrate subject to exposure is carried onto a substrate stage by a predetermined substrate carrier device, and after exposure processing has been completed, the substrate is carried out from the substrate stage by the substrate carrier device. Then, onto the substrate stage, another substrate is carried in by the substrate carrier device. In the exposure apparatus, the exposure processing is consecutively performed to a plurality of substrates by repeatedly performing the carry-in and the carry-out of the substrate as described above. Consequently, when the plurality of substrates are consecutively exposed, it is desirable to speedily perform the carry-in and the carry-out of the substrate onto/from the substrate stage.

### SUMMARY OF THE INVENTION

According to a first aspect of the present invention, there is provided an exposure apparatus that consecutively exposes a plurality of objects with an energy beam, the apparatus comprising: a holding device that holds an object during exposure processing with the energy beam, and is movable in at least one direction within a predetermined plane parallel to a surface of the object with respect to the energy beam; a first carrier device that carries out the object on the holding device, from the holding device; and a second carrier device that carries in another object onto the holding device in a state where a part of the object subject to carry-out is located on the holding device.

With this apparatus, an object is carried out from the holding device by the first carrier device, and on the carry-out, another object is carried in onto holding device by the second carrier device in a state where a part of the object subject to carry-out is located on the holding device. In other words, on the holding device, the carry-out of an object and the carry-in of another object are performed partly in parallel. Consequently, it becomes possible to improve the entire throughput of when a plurality of objects are consecutively exposed.

According to a second aspect of the present invention, there is provided an exchange method of an object to exchange an object held on a holding device that is movable in at least one direction within a predetermined plane parallel to a surface of the object, for another object, the method comprising: carrying out the object on the holding device, from the holding device; and carrying in another object onto the holding device in a state where a part of the object is located on the holding device.

With this method, in a state where a part of an object subject to carry-out is located on the holding device, another object is carried in onto the holding device. In other words, on the holding device, the carry-out of an object and the carry-in of another object are performed partly in parallel. Consequently, it becomes possible to improve the entire throughput of when the processing accompanied by the object exchange on the holding device is performed.

According to a third aspect of the present invention, there is provided a first exposure method of consecutively exposing a plurality of objects, the method comprising: exchanging the object held on a holding device for another one of the objects, with the exchange method of the object described above; and exposing the object after exchange on the holding device with an energy beam.

According to a fourth aspect of the present invention, there is provided a second exposure method of consecutively exposing a plurality of objects, the method comprising: setting a first path and a second path in one direction parallel to a predetermined plane, respectively on one side and the other side of an object exchange position, carrying out an object after exposure from a holding device located at the exchange position along one of the first path and the second path, and carrying in an object before exposure onto the holding device located at the exchange position along the other of the first path and the second path; and exposing the object before exposure on the holding device with an energy beam.

With this method, it becomes possible to improve the entire throughput of when a plurality of objects are consecutively exposed. Further, the prompt object exchange can be performed also in the case where a space above the holding device is small.

According to a fifth aspect of the present invention, there is provided a first device manufacturing method, comprising: exposing the object using the exposure apparatus described above; and developing the object that has been exposed.

Further, according to a sixth aspect of the present invention, there is provided a first flat-panel display manufacturing method, comprising: exposing a substrate used for a flat-panel display as the object, using the exposure apparatus described above; and developing the substrate that has been exposed.

Further, according to a seventh aspect of the present invention, there is provided a second device manufacturing method, comprising: exposing the object, with one of the first and the second exposure methods described above; and developing the object that has been exposed.

Further, according to an eighth aspect of the present invention, there is provided a second flat-panel display manufacturing method, comprising: exposing a substrate used for a flat-panel display as the object, with one of the first and the second exposure methods described above; and developing the substrate that has been exposed.

### BRIEF DESCRIPTION OF DRAWINGS

In the accompanying drawings;

FIG. 1A is a side view schematically showing an exposure apparatus related to a first embodiment when viewed from a −Y side, and FIG. 1B is a side view of the exposure apparatus shown in FIG. 1A when viewed from a +X side;

FIG. 2 is a plan view showing the exposure apparatus related to the first embodiment;

FIG. 3 is a plan view showing a substrate holder and a substrate exchanging device;

FIG. 4A is a plan view showing a substrate tray, FIG. 4B is a side view of the substrate tray shown in FIG. 4A when viewed from the +X side, and FIG. 40 is a cross-sectional view showing the substrate holder that houses the substrate tray;

FIGS. 5A and 5B are cross-sectional views showing the substrate holder, and FIGS. 5C and 5D are cross-sectional views showing a first carrier unit;

FIGS. 6A to 6C are views (No. 1 to No. 3) used to explain the substrate exchange procedure;

FIGS. 7A to 7C are views (No. 4 to No. 6) used to explain the substrate exchange procedure;

FIG. 8A is a plan view corresponding to FIG. 6B, and FIG. 8B is a plan view corresponding to FIG. 7A;

FIGS. 9A and 9B are views (No. 1 and No. 2) used to explain the substrate exchange procedure related to a first modified example;

FIG. 10A is a plan view showing an exposure apparatus related to a second modified example, FIG. 10B is a side view of the exposure apparatus shown in FIG. 10A when viewed from the −Y side, and FIG. 10C is a side view of the exposure apparatus shown in FIG. 10A when viewed from the +X side;

FIGS. 11A and 11B are plan views showing an exposure apparatus related to a third modified example;

FIG. 12 is a plan view schematically showing an exposure apparatus related to a second embodiment;

FIG. 13 is a schematic plan view showing a substrate holder and a substrate exchanging device that the exposure apparatus shown in FIG. 12 is equipped with;

FIG. 14A is a cross-sectional view showing the substrate holder that the exposure apparatus shown in FIG. 12 is equipped with, and FIG. 14B is a cross-sectional view showing a substrate carry-out device;

FIGS. 15A to 15C are views (No. 1 to No. 3) used to explain the substrate exchange procedure in the exposure apparatus related to the second embodiment;

FIGS. 16A to 16D are views (No. 4 to No. 7) used to explain the substrate exchange procedure; and

FIG. 17A is a plan view corresponding to FIG. 15B, and FIG. 17B is a plan view corresponding to FIG. 16A.

### DESCRIPTION OF EMBODIMENTS

### First Embodiment

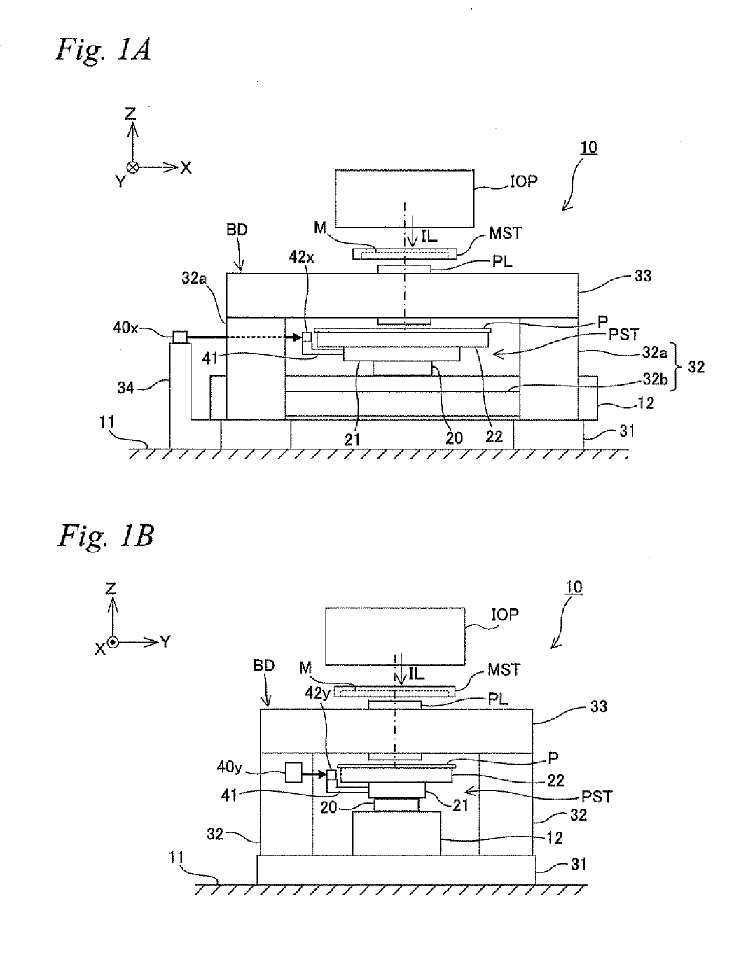

A first embodiment of the present invention is described below, with reference to FIGS. 1A to 8B.

FIG. 1A schematically shows a configuration of an exposure apparatus 10 related to the first embodiment. Exposure apparatus 10 is used in manufacturing of, for example, flat-panel displays, liquid crystal display devices (liquid crystal panels) or the like. Exposure apparatus 10 is a projection exposure apparatus in which a rectangular (quadrate) glass substrate P (hereinafter, simply referred to as a substrate P), which is used for a display panel of a liquid crystal display device or the like, serves as an exposure subject.

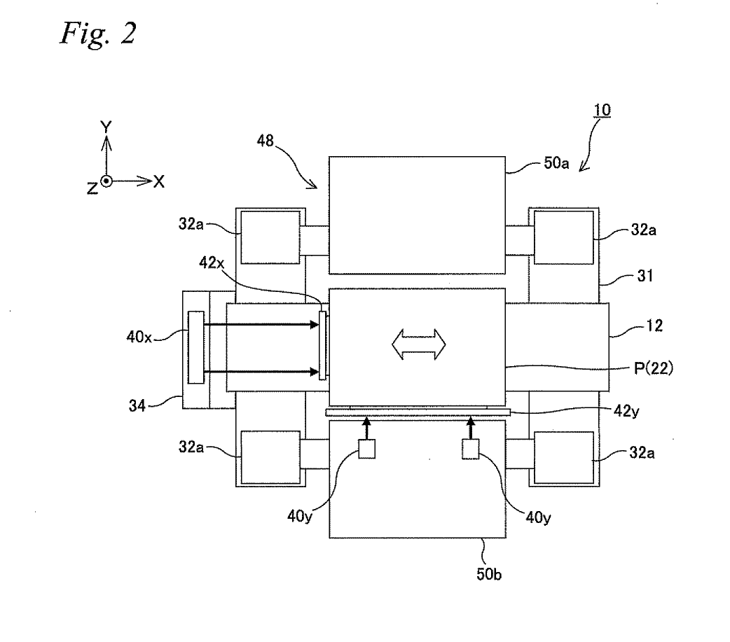

Exposure apparatus 10 is equipped with an illumination system IOP, a mask stage MST that holds a mask M, a projection optical system PL, a body BD on which mask stage MST and projection optical system PL described above and the like are mounted, a substrate stage device PST that holds a substrate P, a substrate exchanging device 48 (not illustrated in FIG. 1A, see FIG. 2), and their control system and the like. In the description below, the explanation is given assuming that a direction in which mask M and substrate P are relatively scanned with respect to projection optical system PL, respectively, during exposure is an X-axis direction (X direction), a direction orthogonal to the X-axis direction within a horizontal plane is a Y-axis direction (Y direction), and a direction orthogonal to the X-axis and the Y-axis is a Z-axis direction (Z direction), and rotational (tilt) directions around the X-axis, Y-axis and Z-axis are θx, θy and θz directions, respectively.

Illumination system IOP is configured similar to the illumination system that is disclosed in, for example, U.S. Pat. No. 5,729,331 and the like. More specifically, illumination system IOP irradiates mask M with a light emitted from a light source that is not illustrated (e.g. a mercury lamp), as an illumination light for exposure (illumination light) IL, via a reflection mirror, a dichroic mirror, a shutter, a wavelength selecting filter, various types of lenses and the like, which are not illustrated. As illumination light IL, for example, a light such as an i-line (with a wavelength of 365 nm), a g-line (with a wavelength of 436 nm) or an h-line (with a wavelength of 405 nm) (or a synthetic light of the i-line, the g-line and the h-line described above) is used. Further, the wavelength of illumination light IL can be switched as needed by the wavelength selecting filter, for example, in accordance with the required resolution.

On mask stage MST, mask M having a pattern surface (the lower surface in FIG. 1A) on which a circuit pattern and the like are formed is fixed by, for example, vacuum adsorption (or electrostatic adsorption). Mask stage MST is driven with predetermined strokes in a scanning direction (the X-axis direction) and also is finely driven in each of the Y-axis direction and the θz direction as needed by a mask stage driving system (the illustration is omitted) that includes, for example, a linear motor. Positional information of mask stage MST within the XY plane (which includes rotational information in the θz direction) is measured by a mask interferometer system, not illustrated, including a plurality of laser interferometers that irradiate a reflection surface arranged (or formed) at mask stage MST with measurement beams.

Projection optical system PL is supported below mask stage MST in FIG. 1, by a barrel surface plate 33 that is a part of body BD. Projection optical system PL is configured similar to the projection optical system disclosed in, for example, U.S. Pat. No. 5,729,331. More specifically, projection optical system PL includes a plurality of projection optical systems (multi-lens projection optical systems) in which projection areas of pattern images of mask M are placed in, for example, a zigzag shape, and functions equivalently to a projection optical system that has a single rectangular (band-shaped) image field whose longitudinal direction is in the Y-axis direction. In the present embodiment, as each of the plurality of projection optical systems, for example, a both-side telecentric equal-magnification system that forms an erected normal image is used. In the description below, the plurality of projection areas placed in a zigzag shape of projection optical system PL are referred to as an exposure area as a whole.

Therefore, when an illumination area on mask M is illuminated with illumination light IL from illumination system IOP, by illumination light IL that has passed through mask M, a projected image (partial erected image) of a circuit pattern of mask M within the illumination area is formed, via projection optical system PL, on an irradiation area (the exposure area) of illumination light IL, which is conjugate to the illumination area, on substrate P which is placed on the image plane side of projection optical system PL and whose surface is coated with a resist (sensitive agent). Then, by relatively moving mask M with respect to the illumination area (illumination light IL) in the scanning direction (X-axis direction) and also relatively moving substrate P with respect to the exposure area (illumination light IL) in the scanning direction (X-axis direction) by synchronous drive of mask stage MST and substrate stage device PST, scanning exposure of one shot area (divided area) on substrate P is performed, and a pattern of mask M is transferred onto the shot area. In other words, in exposure apparatus 10, a pattern of mask M is generated on substrate P by illumination system IOP and projection optical system PL, and the pattern is formed on substrate P by exposure of a sensitive layer (resist layer) on substrate P with illumination light IL.

As disclosed in, for example, U.S. Patent Application Publication No. 2008/0030702 and the like, body BD has a base 31 and barrel surface plate 33 that is horizontally supported on base 31 via a pair of side columns 32. Base 31 includes two members extending in the Y-axis direction placed at a predetermined distance in the X-axis direction (see FIG. 1A), and is installed on a floor surface 11 via a vibration isolation device that is not illustrated, as shown in FIG. 1B. The pair of side columns 32 are placed at a predetermined distance in the Y-axis direction. As shown in FIG. 1A, each of the pair of side columns 32 has a pair of Z columns 32a, and an X beam 32b that connects the vicinities of the lower ends of the pair of Z columns 32a to each other (in FIG. 1A, side column 32 on the +Y side is hidden in the depth of the page surface). Barrel surface plate 33 is made up of a tabular member parallel to the XY plane, and has both ends in the Y-axis direction supported from below by the pair of side columns 32.

Substrate stage device PST is equipped with a surface plate 12, a coarse movement stage 20, a fine movement stage 21, a substrate holder 22 and the like.

As shown in FIG. 2, surface plate 12 is made up of a plate-shaped member formed by, for example, a stone material and having a rectangular shape in a planar view (when viewed from the +Z side) whose longitudinal direction is in the X-axis direction, and its upper surface is finished so as to have a very high flatness degree. Surface plate 12 is mounted in a state installed across the two members extending in the Y-axis direction that configure base 31. Incidentally, in order to avoid intricacy of the drawing, the illustration of barrel surface plate 33, projection optical system PL, illumination system IOP and the like shown in FIG. 1A is omitted in FIG. 2.

Referring back to FIG. 1B, coarse movement stage 20 is mounted on surface plate 12 and is driven with predetermined strokes in the X-axis direction by, for example, a stage driving system including a linear motor that is not illustrated. Incidentally, it is also possible that coarse movement stage 20 is driven with predetermined strokes in the X-axis direction by, for example, another electric actuator such as a planar motor, a feed screw device, or a towing device using a wire or the like.

Fine movement stage 21 is mounted on coarse movement stage 20 via a Z-tilt drive device (e.g. including a voice coil motor) that is not illustrated, and is driven with fine strokes in at least one direction of the Z-axis, the θx, the θy and the θz directions. To fine movement stage 21, an X movable mirror 42x having a reflection surface orthogonal to the X-axis as shown in FIG. 1A and a Y movable mirror 42y having a reflection surface orthogonal to the Y-axis as shown in FIG. 1B are fixed each via a mirror base 41.

Positional information of fine movement stage 21 (not illustrated in FIG. 2, see FIG. 1A) is obtained by an interferometer system that includes an X interferometer 40x and a pair (two) of Y interferometers 40y, as shown in FIG. 2 as an example. Two Y interferometers 40y are placed part in the X-axis direction. X interferometer 40x is fixed to base 31 via an interferometer base 34. Further, two Y interferometers 40y are fixed to side column 32 on the −Y side each via a bracket that is not illustrated (or to the lower surface of barrel surface plate 33 (see FIG. 1A) in a suspended state).

X interferometer 40x irradiates X movable mirror 42x with a pair of X measurement beams that are apart in the Y-axis direction. The interferometer system receives reflected lights of the pair of X measurement beams, and based on the light-receiving results, obtains positional information of fine movement stage 21 in the X-axis direction and positional information of fine movement stage 21 in the θz direction. Two Y interferometers 40y each irradiate Y movable mirror 42y with a Y measurement beam. The attachment positions of two Y interferometers 40y are set such that at least one of the Y measurement beams is irradiated on Y movable mirror 42y regardless of the position of fine movement stage 21 in the X-axis direction. The interferometer system receives a reflected light of at least one of the two Y measurement beams, and based on the light-receiving results, obtains positional information of fine movement stage 21 in the Y-axis direction.

Referring back to FIG. 1A, substrate holder 22 is made up of a plate-shaped member and is fixed on fine movement stage 21. On the upper surface of substrate holder 22, a plurality of minute protrusions that are not illustrated are formed, and substrate P is mounted on the plurality of protrusions. Further, substrate holder 22 has an adsorption device (e.g. a vacuum adsorption device) and holds by adsorption substrate P on the upper surface by generating negative pressure in a space between the plurality of minute protrusions. Incidentally, it is also possible that substrate stage device PST has a weight cancelling device (empty-weight supporting device) that reduces the load of the Z-tilt drive device described previously by cancelling the weight of fine movement stage 21 and substrate holder 22, as disclosed in, for example, U.S. Patent Application Publication No. 2010/0018950 and the like.

Next, substrate exchanging device 48 is described. As shown in FIG. 2, substrate exchanging device 48 includes a first carrier unit 50a and a second carrier unit 50b, and delivers substrate P, as needed, between substrate holder 22 and first carrier unit 50a and between substrate holder 22 and second carrier unit 50b. First carrier unit 50a is placed between a pair of Z columns 32a that configure side column 32 on the +Y side and second carrier unit 50b is placed between a pair of Z columns 32a that configure side column 32 on the −Y side. Incidentally, although not illustrated in FIG. 2, first carrier unit 50a and second carrier unit 50b are installed on floor surface 11 (see FIG. 1A) each via a frame that is not illustrated, in a state separated in terms of vibration from body BD, substrate stage device PST and the like, such that the height (position in the Z-axis direction) of the carrier units from floor surface 11 are substantially the same as that of substrate holder 22.

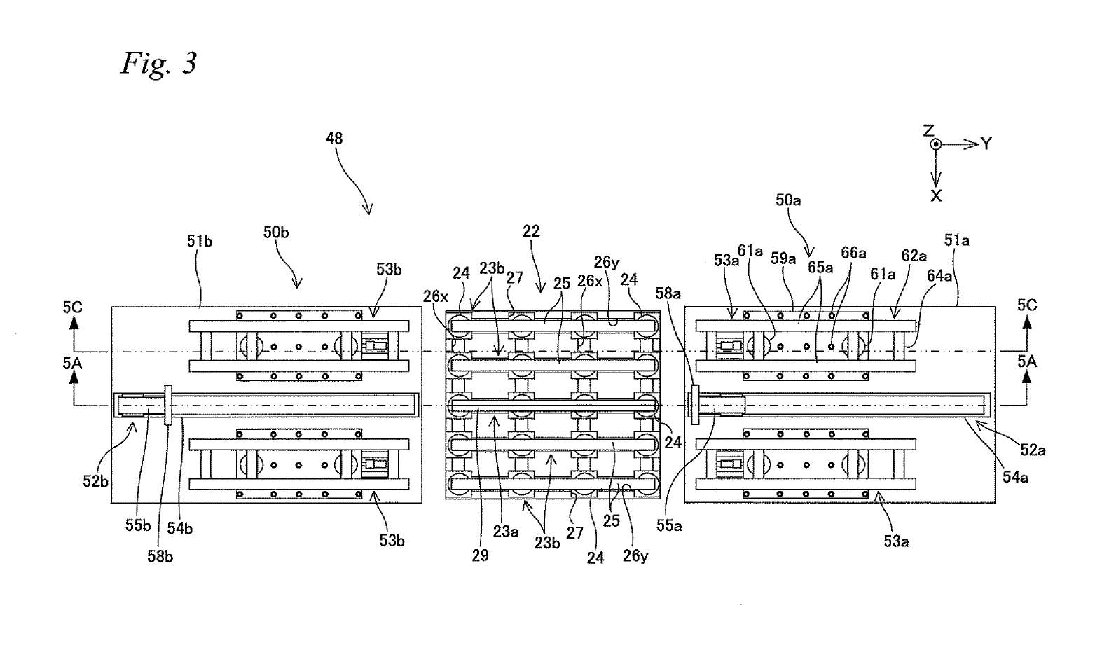

As shown in FIG. 3, first carrier unit 50a has a base 51a, a traveling unit 52a and a pair of air levitation units 53a.

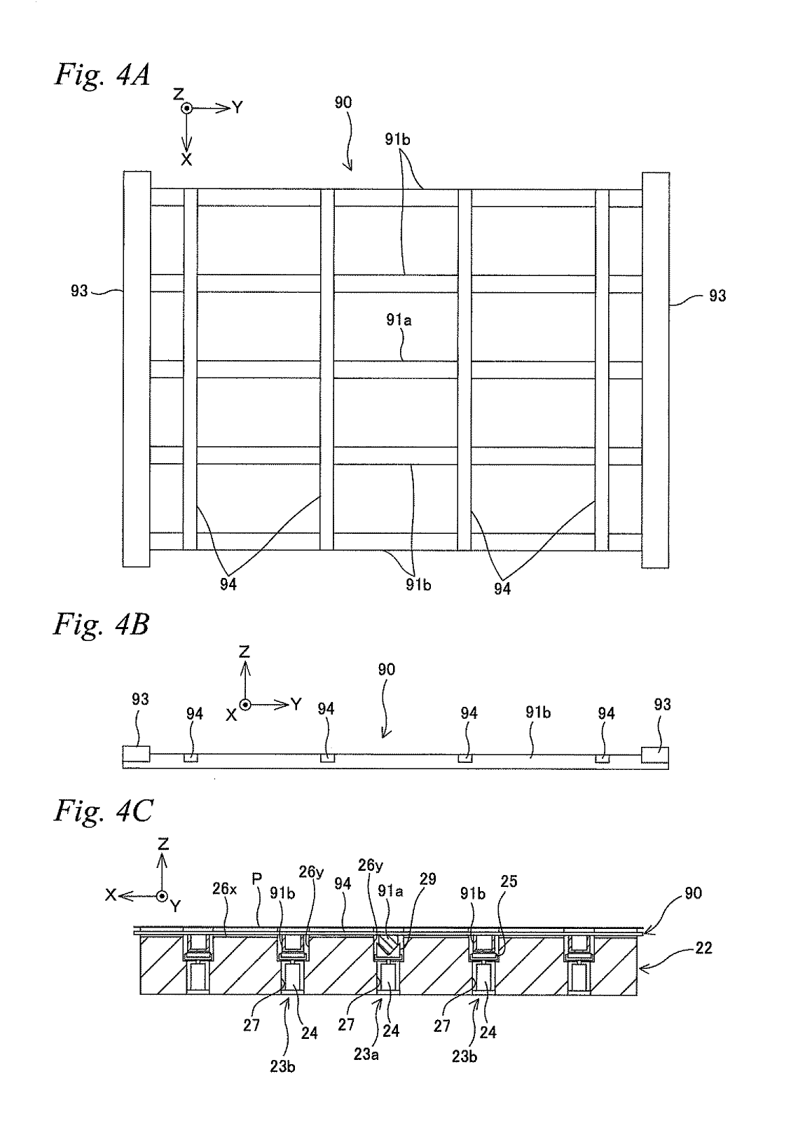

Base 51a is made up of a tabular member having a rectangular shape in a planar view (when viewed from the +Z direction) whose longitudinal direction is in the Y-axis direction, and is placed parallel to the XY plane. Running unit 52a includes a stator section 54a that is fixed to the center portion of the upper surface of base 51a and a mover section 55a mounted on stator section 54a. Stator section 54a is made up of a member extending in the Y-axis direction and has a stator (the illustration is omitted), e.g., a magnet unit or the like. Mover section 55a has a mover (the illustration is omitted), e.g., a coil or the like. The mover that mover section 55a has and the stator that stator section 54a has configure, for example, a Y liner motor that drives mover section 55a with predetermined strokes in the Y-axis direction on stator section 54a. Mover section 55a has a holding member, e.g., an adsorption pad 58a at the end on the −Y side (the substrate stage device PST (substrate holder 22) side). For example, a vacuum suction device that is not illustrated is connected to adsorption pad 58a and adsorption pad 58a holds by adsorption a substrate tray 90 (not illustrated in FIG. 3, see FIG. 4A) to be described later, on its −Y side surface. Incidentally, a device used to drive mover section 55a (i.e. adsorption pad 58a) in the Y-axis direction is not limited to the linear motor, but can be, for example a feed screw device or the like. Further, instead of adsorption pad 58a that holds substrate tray 90 by adsorption, a holding member including a mechanical chuck that mechanically holds (grips) substrate tray 90 can be arranged at mover section 55a.

Of the pair of air levitation units 53a, one air levitation unit 53a is placed on the +X side of traveling unit 52a and the other is placed on the −X side of traveling unit 52a. The pair of air levitation units 53a are substantially the same units except that their placements are different. The pair of air levitation units 53a are synchronously driven by a main controller that is not illustrated. In this case, the drive of the pair of air levitation units 53 is not limited to the synchronous drive, but can be a temporally-shifted drive.

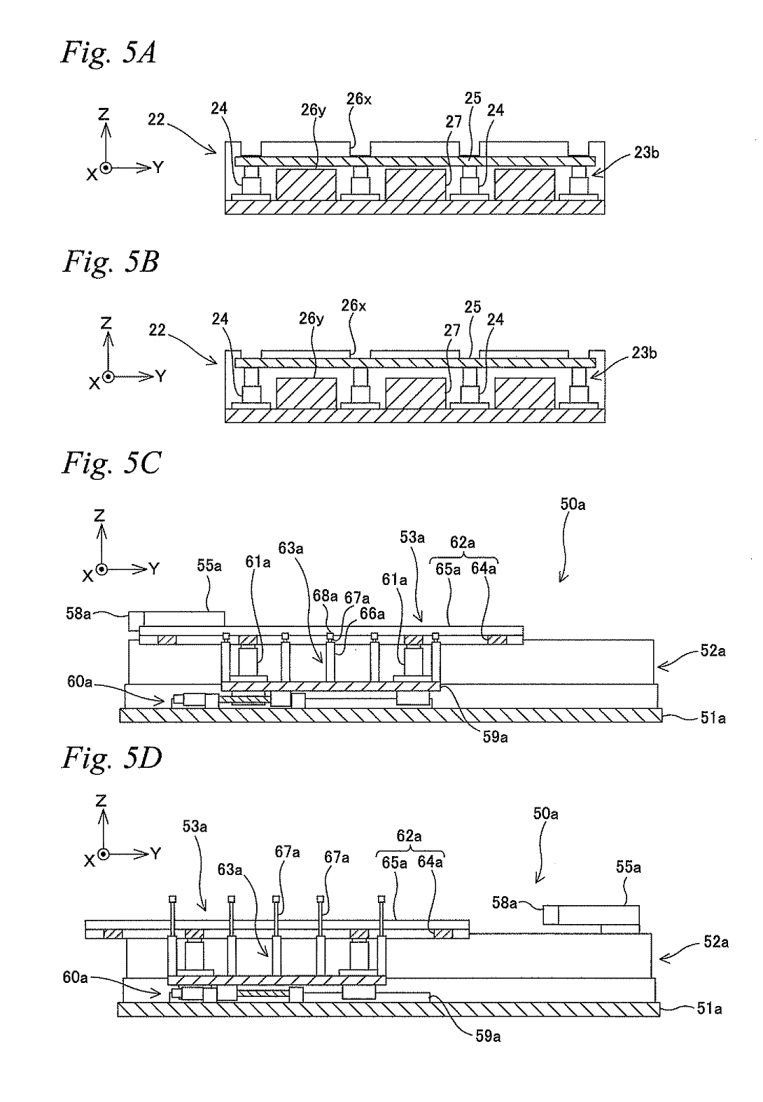

As shown in FIG. 5C, air levitation units 53a each have a movable base 59a, a Y drive unit 60a, a pair of air cylinders 61a, an air levitation device 62a and a substrate lift device 63a. Incidentally, FIG. 5C shows a part of a cross-sectional view sectioned by a line 5C-5C in FIG. 3 (the first carrier unit 50a section), and FIG. 5A shows a part of a cross-sectional view sectioned by a line 5A-5A in FIG. 3 (the substrate holder 22 section).

Movable base 59a is made up of a tabular member having a rectangular shape in a planar view whose longitudinal direction is in the Y-axis direction, and is placed parallel to the XY plane. Y drive unit 60a includes, for example, a feed screw device, a Y linear guide device and the like, and drives movable base 59a with predetermined strokes in the Y-axis direction. FIG. 5D shows a state where movable base 59a is driven in the −Y direction further than the position shown in FIG. 5C by Y drive unit 60a and is located at a movement limit position on the −Y side. Incidentally, a device used to drive movable base 59a in the Y-axis direction is not limited to the feed screw device, but can be, for example, a liner motor, an air cylinder or the like.

The pair of air cylinders 61a are placed at a predetermined distance in the Y-axis direction and are each fixed to the upper surface of movable base 59a. Each of the pair of air cylinders 61a has a rod that is movable in the Z-axis direction. The pair of air cylinders 61a are synchronously driven by the main controller that is not illustrated. In this case, the drive of the pair of air cylinders 61a is not limited to the synchronous drive but can be a temporally-shifted drive.

Air levitation device 62a has a frame 64a that is assembled into a ladder shape in a planar view (see FIG. 3) and a pair of porous members 65a mounted on frame 64a, and frame 64a is attached to the tip of the rod of each of the pair of air cylinders 61a. The pair of porous members 65a are each made up of a plate-shaped member extending in the Y-axis direction and are placed parallel to each other at a predetermined distance in the X-axis direction (FIG. 3). Porous members 65a levitate and support substrate tray 90 (not illustrated in FIG. 5C, see FIG. 4A), to be described later, from below in a noncontact manner by blowing out a pressurized gas (e.g. air), from their upper surfaces, supplied from a gas supplying device provided outside that is not illustrated. It is also possible that plate-shaped members in which a plurality of holes are opened by, for example, machining process, are used instead of porous members 65a and the pressurized gas (e.g. air) is blown out from the upper surfaces via the plurality of holes of the plate-shaped members. As shown in FIG. 5D, air levitation device 62a can move to a position where its −Y side end protrudes on the −Y side further than base 51a, by movable base 59a being driven to the −Y side by Y drive unit 60a.

Referring back to FIG. 5C, substrate lift device 63a includes a plurality (e.g. thirteen in the present embodiment (see FIG. 3)) of air cylinders 66a. The plurality of air cylinders 66a spread at a predetermined distance and are fixed to the upper surface of movable base 59a. Air cylinders 66a each have a rod 67a that is movable in the Z-axis direction, and a pad member 68a that supports the lower surface of substrate P (the illustration is omitted) is attached to the tip (the +Z side end) of rod 67a. The plurality of air cylinders 66a vertically move substrate P by, for example, being driven in synchronization by the main controller that is not illustrated. In this case, the drive of plurality of air cylinders 66a is not limited to the synchronous drive but can be a temporally-shifted drive. Hereinafter, the description is made referring to rods 67a of air cylinders 66a as lift pins 67a. Incidentally, it is also possible that the plurality of lift pins 67a are fixed to a predetermined base member and substrate P is vertically moved by driving the base member in the Z-axis direction.

While being placed bilaterally symmetric to first carrier unit 50a in FIG. 3, second carrier unit 50b is configured similarly to first carrier unit 50a. In the description below, for the sake of convenience of the description, as for the respective components of second carrier unit 50b, the same reference signs of the corresponding components of first carrier unit 50a whose last code “a” is replaced with “b” are used.

In the present embodiment, the substrate exchange on substrate holder 22 using substrate exchanging device 48 is performed using a member that is referred to as substrate tray 90 shown in FIGS. 4A and 4B. Substrate tray 90 can restrain deformation (such as bending) of substrate P, for example, owing to the self weight and can also be called a substrate mounting member, a carriage auxiliary member, a deformation restraining member or a substrate supporting member.

Substrate tray 90 has a first support section 91a, a plurality (e.g. four in the present embodiment) of second support sections 91b, a pair of interlinking members 93, a plurality (e.g. four in the present embodiment) of stiffening members 94, and the like. First support section 91a is made up of a bar-shaped member extending in the Y-axis direction and the sectional (XZ sectional) shape orthogonal to its longitudinal direction is a pentagonal shape (see FIG. 4C). The size in the longitudinal direction of first support section 91a is set to be longer than that of substrate P. Each of second support sections 91b is made up of a hollow member extending in the Y-axis direction with substantially the same length as first support section 91a, and the sectional (XZ sectional) shape orthogonal to its longitudinal direction is substantially a square shape (see FIG. 4C). Substrate tray 90 supports substrate P (the illustration is omitted in FIG. 4A, see FIG. 4C) from below using first support section 91a and four second support sections 91b. For example, of four second support sections 91b, two second support sections 91b are placed on the side of first support section 91a and the other two are placed on the −X side of first support section 91a. First support section 91a and four second support sections 91b are placed at a predetermined distance in the X-axis direction, parallel to one another. For example, the positional relation among four second support sections 91b in the X-axis direction corresponds to the positional relation among porous members 65a (see FIG. 3) in the X-axis direction that air levitation unit 53a of first carrier unit 50a has Incidentally, while substrate tray 90 holds substrate P by a frictional force in a state supporting substrate P from below, this is not intended to be limiting, and substrate tray 90 can hold substrate P by adsorption by, for example, vacuum adsorption or the like.

The pair of interlinking members 93 are each made up of a bar-shaped member whose YZ sectional shape is rectangular, extending in the X-axis direction (see FIG. 4B). Interlinking member 93 on the +Y side interlinks the +Y side ends of first support section 91a and four second support sections 91b. And, interlinking member 93 on the −Y side interlinks the −Y side ends of first support section 91a and four second support sections 91b. A plurality of stiffening members 94 are each made up of a bar-shaped member whose YZ sectional shape is rectangular, extending in the X-axis direction (see FIG. 4B). On the upper end surface of each of first support section 91a and for example, four second support sections 91b, as shown in FIG. 4B, a plurality, e.g. four, of recessed sections are formed. Each of the plurality of stiffening members 94 fits into the recessed section of each of first support section 91a and for example, four second support sections 91b, and the upper end surface (the +Z side surface) of each of stiffening members 94a does not protrude to the +Z side further than the upper end surface of each of first support section 91a and for example, four second support sections 91b. Each of first support section 91a and for example, four second support sections 91b, the pair of interlinking members 93 and four stiffening members 94 is formed by, for example, MMC (Metal Matrix Composites), CFRP (Carbon Fiber Reinforced Plastics), C/C composites (Carbon Fiber Reinforced composites), or the like.

As shown in FIG. 3, on the upper surface of substrate holder 22, a plurality, e.g. five, of groove sections 26y extending in the Y-axis direction are formed at a predetermined distance in the X-axis direction. And, on the upper surface of substrate holder 22, a plurality, e.g. four, of groove sections 26x extending in the X-axis direction are formed at a predetermined distance in the Y-axis direction. The depth of groove sections 26x is set to be shallower than that of groove sections 26y (see FIG. 5A). Further, on the upper surface of substrate holder 22, a recessed section 27 (see FIG. 5A) is formed at intersecting sections (at 20 positions in total) of groove sections 26x and groove sections 26y. The depth of recessed sections 27 is set to be deeper than that of groove sections 26y (see FIG. 5A).

As shown in FIG. 4C, in a state where substrate P is mounted on substrate holder 22, first support section 91a and four second support sections 91b of substrate tray 90 are respectively housed in groove sections 26y. Further, in a state where substrate P is mounted on substrate holder 22, stiffening members 94 of substrate tray 90 are housed in groove sections 26x. The exposure operation with respect to substrate P is performed in a state where first support section 91a and four second support sections 91b of substrate tray 90 are housed in groove sections 26y.

Further, substrate holder 22 has a tray guide unit 23a that supports first support section 91a housed in groove section 26y, from below, and a plurality (four in this case) of air levitation units 23b that respectively support second support sections 91b housed inside four groove sections 26y, from below.

Referring back to FIG. 3, each of tray guide unit 23a and four air levitation units 23b has, for example, four air cylinders 24 disposed at a distance corresponding to a distance between recessed sections 27 described above, in the Y-axis direction. Air cylinders 24 that tray guide unit 23a and four air levitation units 23b each have are housed in recessed sections 27, respectively (see FIG. 4C).

A Y guide member 29 is installed across the rod tips of, for example, four air cylinders 24 that tray guide unit 23a has. Y guide member 29 is made up of a member extending in the Y-axis direction, and on its upper end surface, as shown in FIG. 4C, a groove section whose XZ section has a V shape (V groove) is formed. First support section 91a of substrate tray 90 is inserted into the V groove of Y guide member 29, and thereby relative movement of substrate tray 90 with respect to substrate holder 22 in the X-axis direction is restricted. Meanwhile, as shown in FIG. 3, an air levitation device 25 is installed across the rod tips of, for example, four air cylinders 24 that air levitation unit 23b has. Air levitation device 25 includes a porous member (which is substantially the same member as porous member 65a of first carrier unit 50a) made up of a tabular member extending in the Y-axis direction, and has the function of levitating second support sections 91b. It is also possible that Y guide member 29 is also made up of a porous member and has a function to restrict relative movement of first support section 91a in the X-axis direction while levitating first support section 91a. Air levitation devices 25 and Y guide member 29 each vertically move within groove section 26y by the plurality of air cylinders 24 being synchronously drive by the main controller that is not illustrated (see FIGS. 5A and 5B). In this case, the drive of the plurality of air cylinders 24 is not limited to the synchronous drive but can be a temporally-shifted drive. Tray guide unit 23a is not limited to a levitation type (noncontact type) but can be a contact type using, for example, bearings or the like. Similarly, instead of air levitation unit 23b, a contact type support mechanism that uses bearings or the like can also be used.

In exposure apparatus 10 (see FIG. 1) configured as described above, under control of the main controller that is not illustrated, loading of mask M onto mask stage MST is performed by a mask carrier device (mask loader) that is not illustrated. And, carry-in (loading) of substrate P onto substrate holder 22 is performed by one of first carrier unit 50a and second carrier unit 50b. After that, the main controller executes alignment measurement using an alignment detection system that is not illustrated, and after the alignment measurement has been completed, an exposure operation is performed. Because this exposure operation is similar to the conventionally performed one, detailed description thereof is omitted. Then, substrate P that has been exposed is carried out (unloaded) from substrate holder 22 by one of first carrier unit 50a and second carrier unit 50b (the carrier unit that carried in substrate P), and another substrate P is carried into (loaded onto) substrate holder 22 by the other of first carrier unit 50a and second carrier unit 50b. Another substrate P that has been exposed is carried out from substrate holder 22 by the carrier unit that carried in such another substrate P (the other of first carrier unit 50a and second carrier unit 50b). In other words, in exposure apparatus 10, the exposure processing is consecutively performed to a plurality of substrates P by the exchange of substrate P on substrate holder 22 being repeatedly performed.

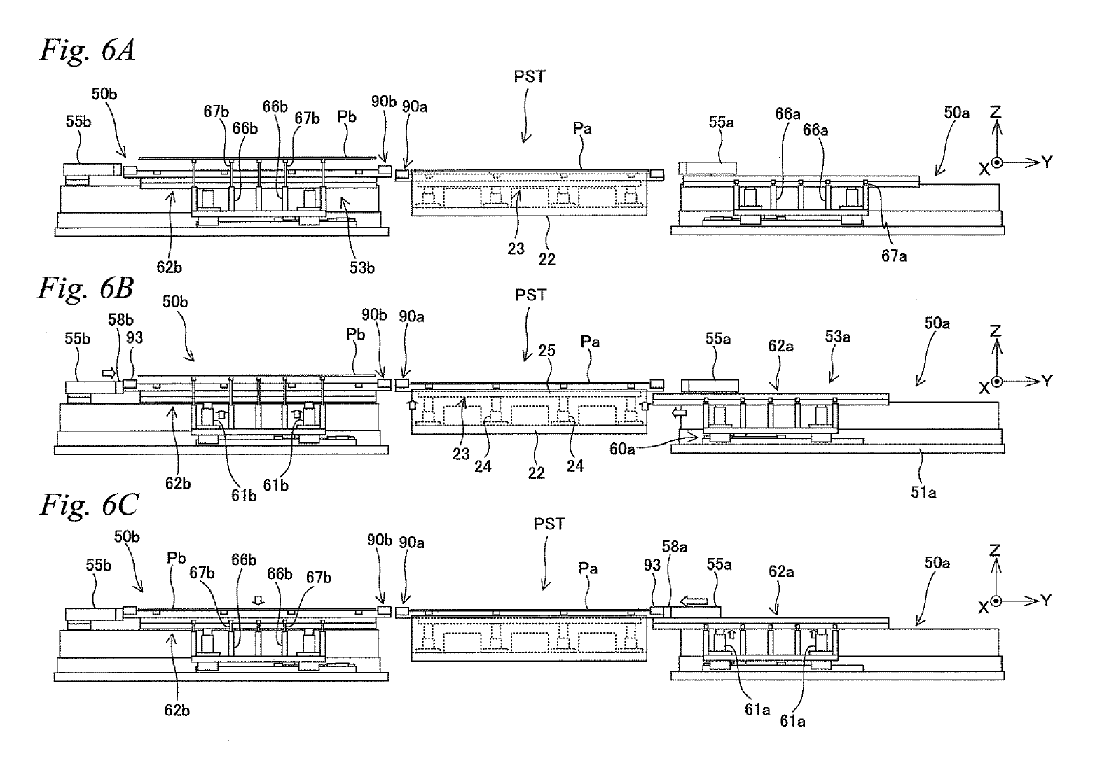

The exchange procedure of substrate P on substrate holder 22 using first carrier unit 50a and second carrier unit 50b is described below with reference to FIGS. 6A to 8B. Note that FIGS. 6A to 8B are views used to explain the exchange procedure of substrate 2, and of substrate stage device PST, only substrate holder 22 is shown. And, in order to facilitate the understanding, the description is made referring to a substrate after the exposure processing to which the exposure processing has been performed and is carried out from substrate holder 22, as a substrate Pa, and referring to a substrate subject to exposure (to be exposed) that is newly mounted on substrate holder 22, as a substrate Pb, in FIGS. 6A to 8B. The substrate exchange is performed under control of the main controller that is not illustrated.

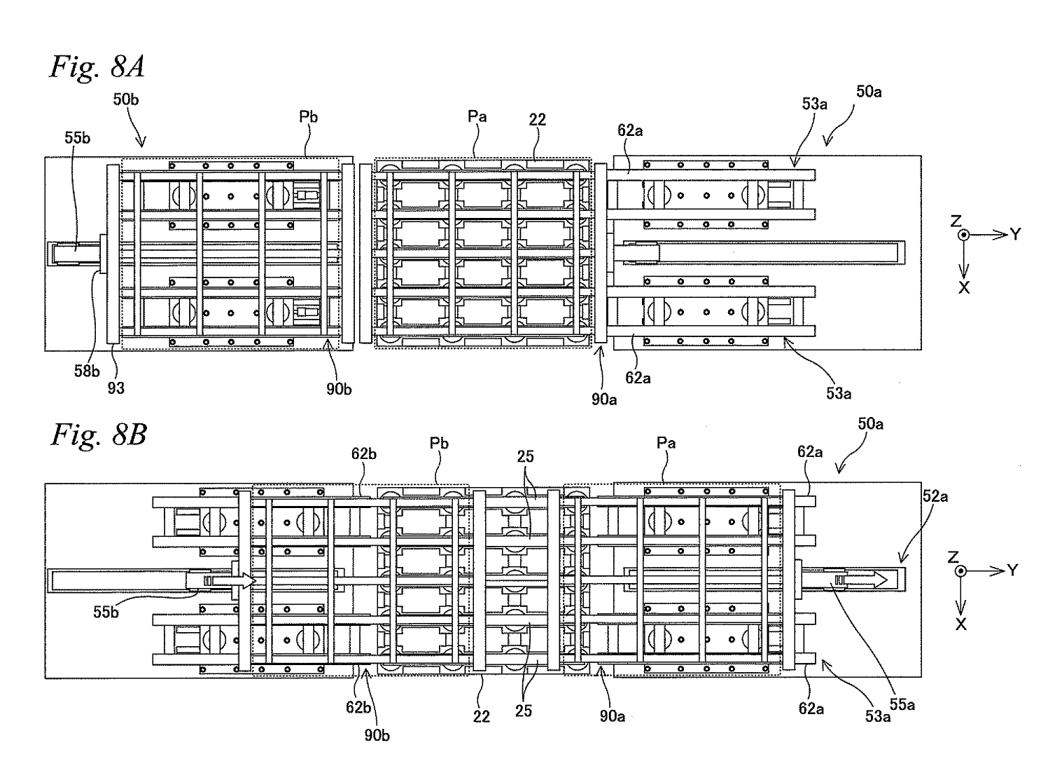

In this case, in the present embodiment, two substrate trays 90 shown in the drawings such as FIG. 4A are used. In the description below, a substrate tray that supports substrate Pa from below is referred to as substrate tray 90a and a substrate tray that supports substrate Pb from below is referred to as substrate tray 90b. Further, from the viewpoint of avoiding intricacy of the drawings, in FIGS. 8A and 8B, substrates Pa and Pb are indicated by broken lines.

FIG. 6A shows substrate stage device PST immediately after the exposure processing with respect to substrate Pa has been completed. On substrate holder 22, substrate Pa after exposure is mounted. Substrate tray 90a is housed in five groove sections 26y (not illustrated in FIG. 6A, see FIG. 3) of substrate holder 22, and is supported from below by tray guide unit 23a and four air levitation units 23b. Substrate holder 22 is located at the substrate exchange position shown in FIG. 2 (the location where the position in the X-axis direction of substrate holder 22 is the same as that of first carrier unit 50a and second carrier unit 50b). Further, in second carrier unit 50b, the plurality of lift pins 67b are in a state located at a movement limit position on the +Z side (upper limit movement position), and substrate Pb to which the exposure processing is to be performed next is supported from below by the plurality of lift pins 67b. Substrate Pb is carried from the outside into exposure apparatus 10 by a robot for substrate carriage, not illustrated, in the middle of performing the exposure processing of substrate Pa, and is mounted on the plurality of lift pins 67b. Substrate tray 90b is supported from below by air levitation devices 62b that the pair of air levitation units 53b respectively have. Further, mover section 55b is located at a movement limit position on the −Y side (the farthest position from substrate holder 22). In contrast, in first carrier unit 50a, mover section 55a is located slightly on the +Y side further than a movement limit position on the −Y side (the closest position to substrate holder 22). Further, the plurality of lift pins 67a are in a state located at the movement limit position on the −Z side (lower limit movement position).

Next, as shown in FIG. 6B, the holding by adsorption of substrate Pa by substrate holder 22 is released for carry-out of substrate Pa after exposure, and air is supplied to the plurality of air cylinders 24 within substrate holder 22. Accordingly, the rod of each of the plurality of air cylinders 24 moves in the direction, substrate tray 90a moves upward (in the +Z direction) and substrate Pa is supported from below by substrate tray 90a. The lower surface of substrate Pa separates from the upper surface of substrate holder 22 by substrate Pa moving together with substrate tray 90a in the +Z direction.

Further, in first carrier unit 50a, each of the pair of air levitation units 53a (movable bases 59a) is driven to the −Y side by Y drive unit 60a and the −Y side end of each of the pair of air levitation devices 62a protrudes to the −Y side further than base 51a (see FIG. 8A that is a plan view corresponding to FIG. 6B). In contrast, in second carrier unit 50b, air is supplied to the pair of air cylinders 61b that each of the pair of air levitation units 53b has (a total of four air cylinders 61b), and accordingly the rod of each of four air cylinders 61b moves in the +Z direction and the pair of air levitation devices 62b and substrate tray 90b move to the +Z side. The Z-position of the upper surface of each air levitation device 62b at this point roughly coincides with the Z-position of the upper surface of each air levitation device 25 that substrate holder 22 has. Further, mover section 55b is driven in the +Y direction and adsorption pad 58b holds by adsorption interlinking member 93 on the −Y side of substrate tray 90b (see FIG. 8A).

Subsequently, as shown in FIG. 6C, air is supplied to the pair of air cylinders 61a that each of the pair of air levitation units 53a of first carrier unit 50a has (a total of four air cylinders 61a) and the rod of each of four air levitation devices 62a moves in the +Z direction, which raises the pair of air levitation devices 62a. The Z-position of the upper surface of each air levitation device 62a at this point roughly coincides with the Z-position of the upper surface of each air levitation device 25 that substrate holder 22 has. Further, mover section 55a is driven in the −Y direction and adsorption pad 58a holds by adsorption interlinking member 93 on the +Y side of substrate tray 90a. Meanwhile, in second carrier unit 50b, the plurality of lift pins 67b are driven in the −Z direction and substrate Pb descends (moves in the −Z direction). Accordingly, substrate Pb is mounted on substrate tray 90b. After substrate Pb has been mounted on substrate tray 90b, the plurality of lift pins 67b are further driven to the -Z side and thereby each lift pin 67b separates from the lower surface of substrate Pb.

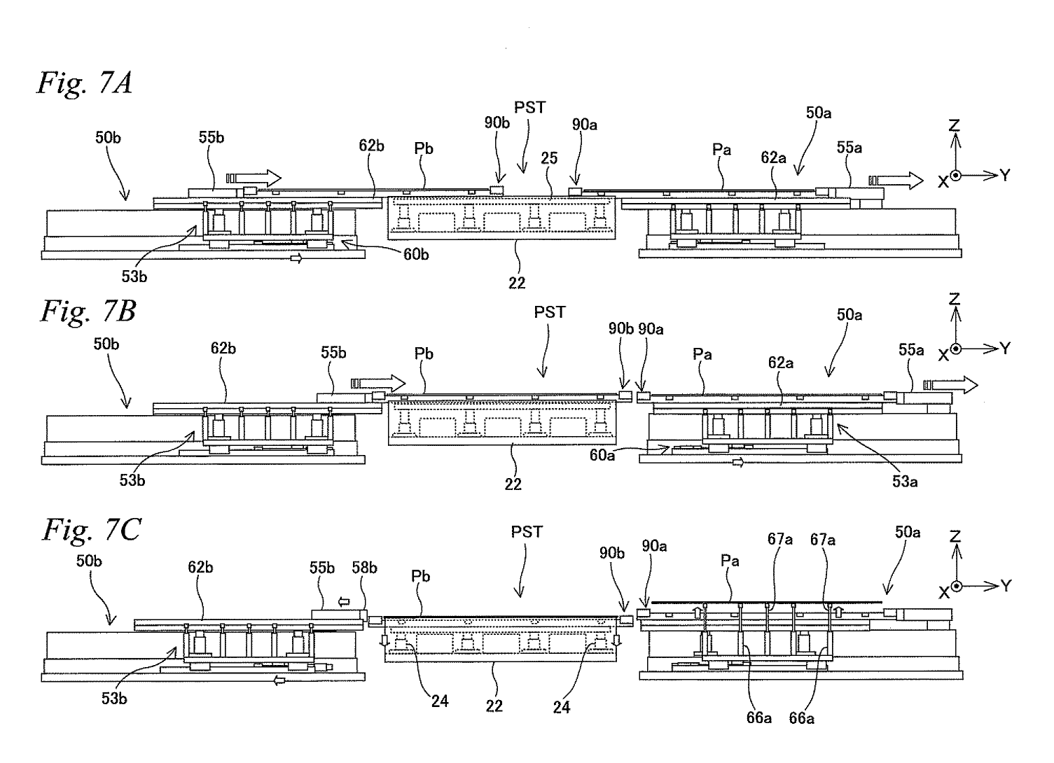

After that, as shown in FIG. 7A, mover section 55a of first carrier unit 50a is driven in the +Y direction. On this operation, the pressurized air is blown out from each of the pair of air levitation devices 62a of first carrier unit 50a and the plurality of air levitation devices 25 of substrate holder 22. Accordingly, substrate tray 90a moves (slides) parallel to a horizontal plane, in a levitated state, from above the plurality of air levitation devices 25 of substrate holder 22 to above the pair of air levitation devices 62a of first carrier unit 50a, and substrate tray 90a is delivered from substrate holder 22 to first carrier unit 50a (see FIG. 8B that is a plan view corresponding to FIG. 7A). Further, in parallel with (in conjunction with) this carry-out operation of substrate tray 90a (substrate Pa) from substrate holder 22, each of the pair of air levitation devices 62b of second carrier unit 50b is driven in the +Y direction by Y drive unit 60b, and the +Y side ends of the pair of air levitation devices 62b approach substrate holder 22. Further, in second carrier unit 50b, mover section 55b is driven in the +Y direction. On this operation, by the pressurized gas being blown out from the pair of air levitation devices 62b, substrate tray 90b moves (slides) parallel to a horizontal plane, in a levitated state, from above the pair of air levitation devices 62b to above the plurality of air levitation devices 25 of substrate holder 22, and substrate tray 90b is delivered from second carrier unit 50b to the plurality of air levitation devices 25 of substrate holder 22 (see FIG. 8B). Incidentally, while in FIGS. 7A and 8B, the replacement (exchange) of the substrate on substrate holder 22 is performed in a state where a predetermined interspace (gap) is formed between the −Y side end (rear end in the carry-out direction) of substrate tray 90a and the +Y side end (front end in the carry-in direction) of substrate tray 90b, this is not intended to be limiting, and the replacement of the substrate on substrate holder 22 can be performed in a state where substrate tray 90a and substrate tray 90b are closer to each other.

Subsequently, as shown in FIG. 7B, in first carrier unit 50a, mover section 55a is further driven in the +Y direction, and substrate tray 90a is completely moved out of substrate holder 22 and mounted on first carrier unit 50a. Then, in accordance with this operation, the pair of air levitation devices 62a are driven in the +Y direction integrally with substrate tray 90a by the pair of Y drive units 60a, respectively. And, in parallel with the forgoing carry-out of substrate tray 90a (substrate Pa) from substrate holder 22, mover section 55b is further driven in the +Y direction in second carrier unit 50b. Accordingly, substrate tray 90b (substrate Pb) is completely delivered from second carrier unit 50b to substrate holder 22.

Next, as shown in FIG. 7C, in first carrier unit 50a, air is supplied to the plurality of air cylinders 66a, each of the plurality of lift pins 67a moves in the +Z direction, and thereby substrate Pa is supported from below and driven upward and is separated from substrate tray 90a. Meanwhile, in second carrier unit 50b, after the holding by adsorption of substrate tray 90b by adsorption pad 58b is released, mover section 55b and the pair of air levitation devices 62b are respectively driven in the −Y direction and returned to the initial positions shown in FIG. 6A. Further, in substrate holder 22, the rods of the plurality of air cylinders 24 are driven to the −Z side and substrate Pb descends together with substrate tray 90a. Accordingly, the lower surface of substrate Pb comes in contact with the upper surface of substrate holder 22 and substrate holder 22 holds substrate Pb by adsorption. Further, also after the lower surface of substrate Pb comes into contact with the upper surface of substrate holder 22, the rods of the plurality of air cylinders 24 are further driven to the −Z side and accordingly, substrate tray 90b and substrate Pb separate from each other, and substrate tray 90b is housed in substrate holder 22.

After that, in first carrier unit 50a, substrate Pa after exposure that is supported by the plurality of lift pins 67a is carried by the substrate carrying robot that is not illustrated, toward an external device (e.g. a coater/developer device). Further, in the middle of performing the exposure processing to substrate Pb mounted on substrate holder 22, another substrate to be exposed next (which is referred to as a substrate Pc, the illustration of substrate Pc is omitted) is carried by the substrate carrying robot that is not illustrated, and mounted on the plurality of lift pins 67a of first carrier unit 50a. Substrate Pc is mounted on substrate tray 90a by the plurality of lift pins 67a being driven to the −Z side. Then, when the exposure processing with respect to substrate Pb mounted on substrate holder 22 is completed, substrate Pb is carried out together with substrate tray 90b from substrate holder 22 by second carrier unit 50b, and with respect to substrate holder 22, substrate tray 90a on which substrate Pc is mounted is carried in by first carrier unit 50a. Afterwards, every time exposure of the substrate on substrate holder 22 is performed, the carry-out and carry-in operations of the substrates by first carrier unit 50a, second carrier unit 50b and substrate holder 22 similar to the above-described ones are repeatedly performed.

In this manner, in the present embodiment, while first carrier unit 50a and second carrier unit 50b alternately interchange the functions as a substrate carry-out device and a substrate carry-in device, the exchange of substrate P mounted on substrate holder 22 is repeatedly performed using two substrate trays 90 (substrate tray 90a used by first carrier unit 50a and substrate tray 90b used by second carrier unit 50b).

As is described above, in exposure apparatus 10 related to the present embodiment, since the carry-in operation of substrate P to substrate holder 22 and the carry-out operation of another substrate P from substrate holder 22 are performed in parallel on substrata holder 22, the entire throughput in the case of consecutively performing the exposure processing to the plurality of substrates P can be improved.

Further, substrate P is mounted on substrate tray 90 and carried, and therefore the bending of substrate P caused by the self weight can be restrained and carriage of substrate P can be performed at a high speed. Further, the possibility that substrate P is damaged can be reduced.

Further, since air levitation units 23b, 53a and 53b are arranged at substrate holder 22, first carrier unit 50a and second carrier unit 50b, respectively, and substrate tray 90 is moved in a levitated state, substrate tray 90 can be moved at a high speed and with low generation of dust. Further, Y guide member 29 on which the V grove is formed is arranged at tray guide unit 23a of substrate holder 22 and substrate tray 90 is linearly guided, and therefore substrate tray 90 can stably be carried in and carried out at a high speed.

Further, since two substrate trays 90 for substrate carry-in and substrate carry-out are moved on the same plane, substrate exchanging device 48 of the present embodiment is effective also in the case where a space above substrate holder 22 is small.

Further, when substrate P is delivered from second carrier unit 50b to substrate holder 22 during the carry-in, the pair of air levitation devices 62b are made to approach substrate holder 22, and therefore the delivery of substrate tray 90 can be performed smoothly. Similarly, also when substrate P is delivered from substrate holder 22 to first carrier unit 50a during the carry-out, the pair of air levitation devices 62a of first carrier unit 50a are made to approach substrate holder 22, and therefore, the delivery of substrate 90 can be performed smoothly.

Incidentally, the configurations of substrate exchanging device 48, substrate stage device PST and the like of the embodiment above are merely examples. Several modified examples of the embodiment above are described below, with a substrate exchanging device and a substrate stage device being focused on.

### FIRST MODIFIED EXAMPLE

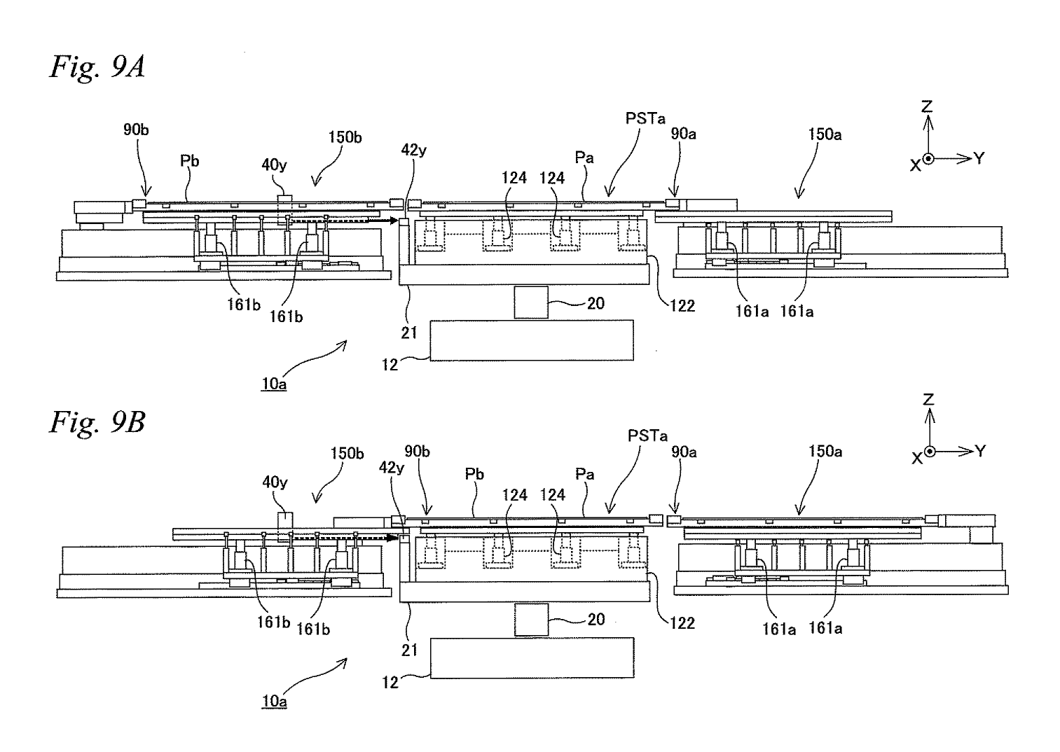

FIG. 9A shows an exposure apparatus 10a related to a first modified example. In exposure apparatus 10a, the Z-position of Y movable mirror 42y used when positional information in the Y-axis direction (Y positional information) of fine movement stage 21 that configures a part of a substrate stage device PSTa is different from that of the embodiment above.

In exposure apparatus 10a, an interferometer system used to obtain the Y positional information of fine movement stage 21 (while FIG. 9A shows only Y interferometer 40y, X interferometer 40x is similar to Y interferometer 40y) irradiates a measurement beam on the same plane as the surface of substrate P (substrate Pa in FIG. 9A) mounted on a substrate holder 122. Accordingly, the positional information of substrate P can be obtained without the Abbe error. Therefore, the Z-position (to be more precise, the position of the +Z edge) of the reflection surface of Y movable mirror 42y, which substrate stage device PSTa has, is set to be higher than the surface (upper surface) of substrate holder 122.

Therefore, in exposure apparatus 10a, the strokes of each air cylinder 161b of a second carrier unit 150b and each air cylinder 124 (see FIG. 9A) of substrate holder 122 are set to be longer than those of each air cylinder 61b and each air cylinder 24 in the embodiment above. With this setting, as shown in FIG. 9B, during delivery of substrate tray 90b to substrate holder 122, substrate tray 90b is slid at a higher position compared with the embodiment above, and contact between substrate tray 90b and Y movable mirror 42y is avoided. Note that as shown in FIGS. 9A and 98, the strokes of each air cylinder 161a of a first carrier unit 150a are also set to be longer than those of the embodiment above, in accordance with each air cylinder 124 of substrate holder 122.

### SECOND MODIFIED EXAMPLE

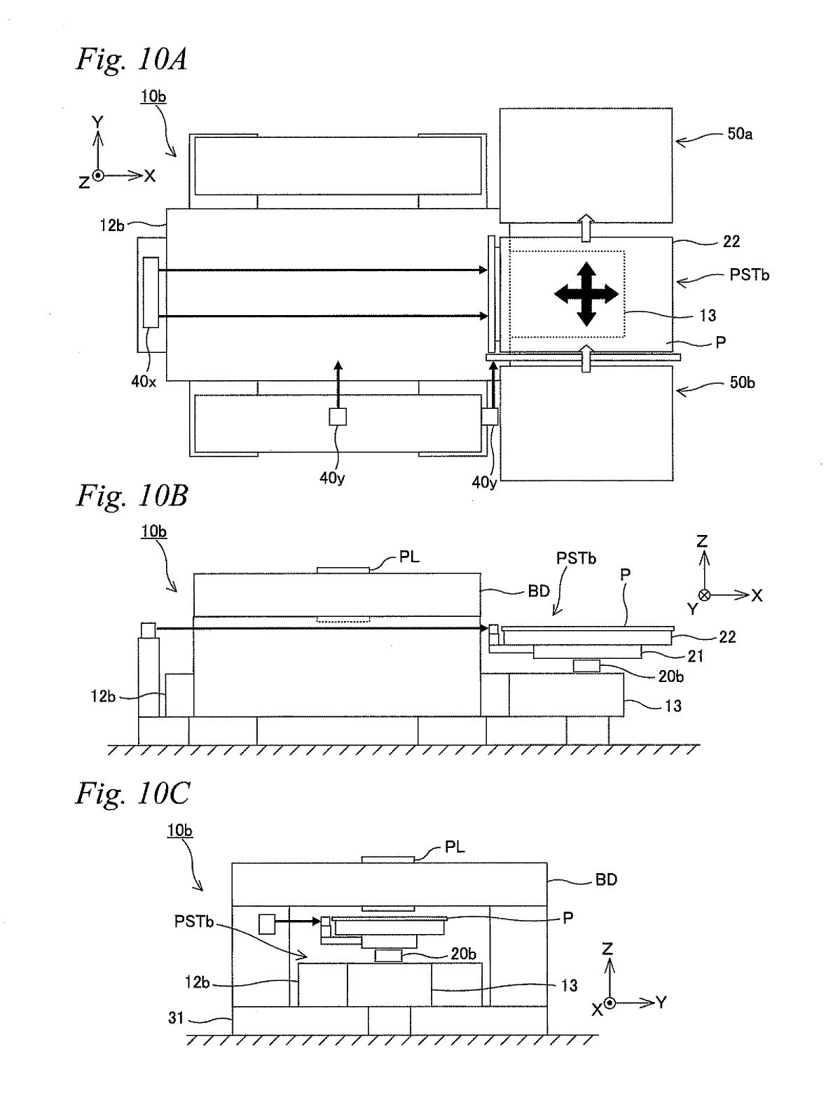

FIGS. 10A to 10C show a schematic configuration of an exposure apparatus 10b related to a second modified example. Exposure apparatus 10b is a projection exposure apparatus by a step-and-scan method (scanning stepper (which is also called a scanner)) that alternately repeats a scan operation and a step operation of substrate P during the exposure operation. Consequently, substrate holder 22 is movable with predetermined strokes in the X-axis direction (scan direction) and the Y-axis direction (step direction), respectively. Therefore, first carrier unit 50a and second carrier unit 50b cannot be placed similarly to those in the embodiment above.

A substrate stage device PSTb which exposure apparatus 10b is equipped with has an auxiliary surface platform 13 on the +X side of a surface plate 12b. Auxiliary surface plate 13 is formed to be continuous with surface plate 12b, and a drive system (such as a liner motor) of substrate stage device PSTb can position coarse movement stage 20 (XY stage) on auxiliary surface plate 13. Note that auxiliary surface plate 13 is used only during exchange of substrate P and is not used during exposure. Further, because the high precision is not required for the drive system used to position coarse movement stage 20 on auxiliary surface plate 13 and for a measurement system, another drive system and another measurement system, different from the drive system for exposure described above and the measurement system (the linear motor and the interferometer system), can be used.

On the +Y side of auxiliary surface plate 13, first carrier unit 50a having substantially the same configuration as that in the embodiment above is placed, and on the −Y side of auxiliary surface plate 13, second carrier unit 50b having substantially the same configuration as that in the embodiment above is placed. In the present second modified example, after the exposure operation with respect to substrate P is performed on surface plate 12b, coarse movement stage 20 is moved onto auxiliary surface plate 13 (see FIG. 10A), and the exchange operation of substrate P is performed at that position. Since the configurations and the operations of first carrier unit 50a and second carrier unit 50b are the same as those in the embodiment above, the description thereof is omitted.

### THIRD MODIFIED EXAMPLE

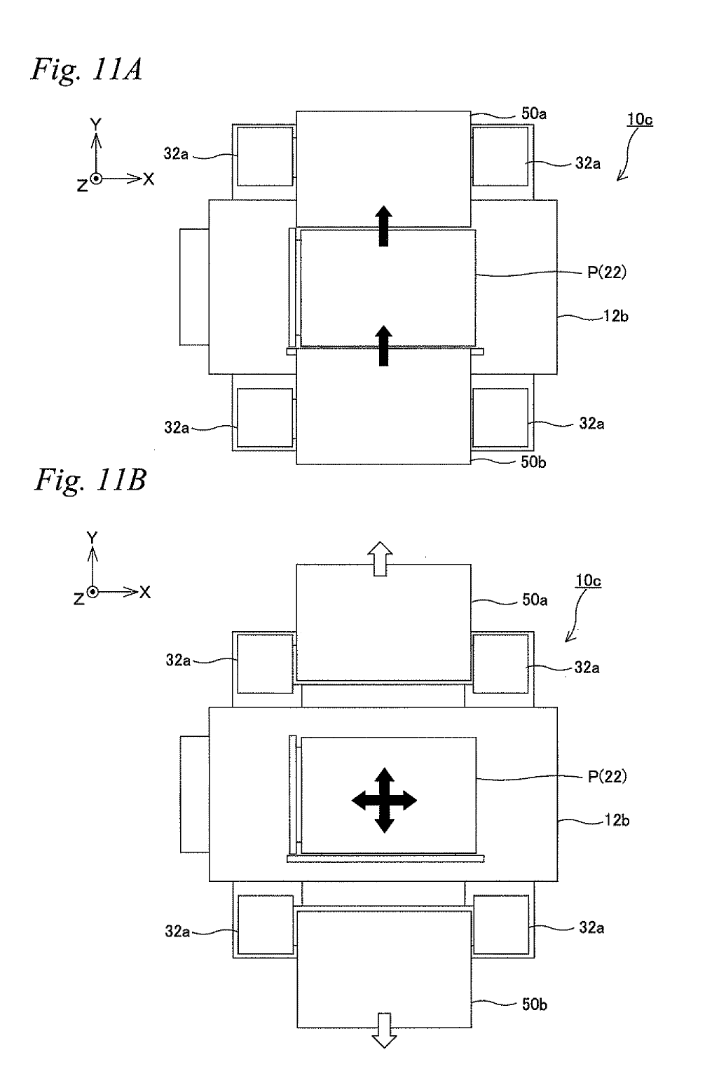

FIG. 11A shows a schematic configuration of an exposure apparatus 10c related to a third modified example, in a plan view. Exposure apparatus 10c is a projection exposure apparatus by a step-and-scan method similar to the second modified example described above. In the present third modified example, similarly to the embodiment above, first carrier unit 50a is placed between the pair of Z columns 32a of side column 32 on the +Y side and second carrier unit 50b is placed between the pair of Z columns 32a of side column 32 on the −Y side.

In the present third modified example, first carrier unit 50a and second carrier unit 50b are movable independently of each other in the Y-axis direction (see outlined arrows in FIG. 11B). First carrier unit 50a and second carrier unit 50b are withdrawn from above surface plate 12b such that the carrier units do not come in contact with substrate holder 22 while exposure apparatus 10c performs the exposure operation (see FIG. 11B), and the carrier units move to the positions in proximity to substrate holder 22 only during the substrate exchange (see FIG. 11A). Consequently, the entire apparatus of exposure apparatus 10c of the present third modified example can be more compact than that in the second modified example described above.

Incidentally, while in the embodiment above, in a state where substrate tray 90 is levitated using air levitation units 23b, 53a and 53b (in a noncontact state), substrate tray 90 is slid along the horizontal plane, this is not intended to be limiting, and for example, substrate tray 90 can be supported from below using a rolling body such as a ball or a skid.

Further, while, in the embodiment above, when substrate tray 90 is delivered from each of first carrier unit 50a and second carrier unit 50b to substrate holder 22, only air levitation devices 62a and 62b approach substrate holder 22 (see FIG. 8B), this is not intended to be limiting if air levitation devices 62a and 62b and substrate holder 22 can be made to approach each other, and for example, it is also possible to make the entire first carrier unit 50a and the entire second carrier unit 50b (i.e. including bases 51a and 51b) approach substrate holder 22.

Further, while, in the embodiment above, first carrier unit 50a and second carrier unit 50b respectively have traveling units 52a and 52b each of which travels in the Y-axis direction holding the center portion of substrate tray 90 in the X-axis direction, a configuration of a traveling unit used to slide substrate tray 90 along the horizontal plane is not limited thereto, and for example, it is also possible that a traveling unit holds two positions spaced apart in the X-axis direction of substrate tray 90. In this case, rotation of substrate tray 90 in the θz direction can reliably be restrained. Further, it is also possible that two traveling units that respectively hold two positions of substrate tray 90 different from each other are provided and the position of substrate tray 90 (i.e. substrate P) in the θz direction is positively controlled by controlling the two traveling units independently (in such a case, substrate tray 90 should be held such that its movement in the θz direction is not restricted). In this case, especially during the substrate carry-in, substrate tray 90 can be delivered onto substrate holder 22 with the respective sides of substrate P being parallel to the X-axis and the Y-axis (measurement axes of the interferometer system). Further, in this case, the support sections (bar-shaped members) of substrate tray 90 (see FIG. 4A) can be configured of only members each having a shape that does not restrict the movement in the X-direction (e.g. a configuration in which first support section 91a is replaced with second support section 91b) (In this case, at substrate holder 22 (see FIG. 3), air levitation unit 23b that corresponds to second support section 91b is arranged in place of tray guide unit 23a).

Further, in the embodiment above, it is also possible that the vacuum adsorption of substrate P by substrate tray 90 is performed during either of the carry-in (loading) or the carry-out (unloading), or the adsorption of the substrate needs not be performed in both of the carry-in and the carry-out. In other words, the adsorption of the substrate during the carry-out and the carry-in is not essential. For example, whether the adsorption is necessary or not can be determined depending on the movement speed (acceleration) of substrate P, and/or a displacement amount of substrate P with respect to substrate tray 90 or a permissible value of the displacement amount. Especially, the permissible value in the latter case, for example, corresponds to the pre-alignment accuracy during the carry-in and corresponds to a permissible value used to prevent falling or collision and/or contact with the other members owing to the displacement during the carry-out.

Further, in the embodiment above, the holding member of the substrate used to restrain and/or prevent the relative displacement (movement) between substrate P and substrate tray 90 during the movement is not limited to the vacuum chuck or the like that performs vacuum adsorption, but instead of or in combination with the vacuum chuck or the like, another method can also be used, e.g., a holding member that sandwiches the substrate with a plurality of fixing sections (pins) or a holding member by a method in which at least one fixing section is movable and the plate side surface is pressed against the fixing section, or a clamp mechanism or the like.

### Second Embodiment

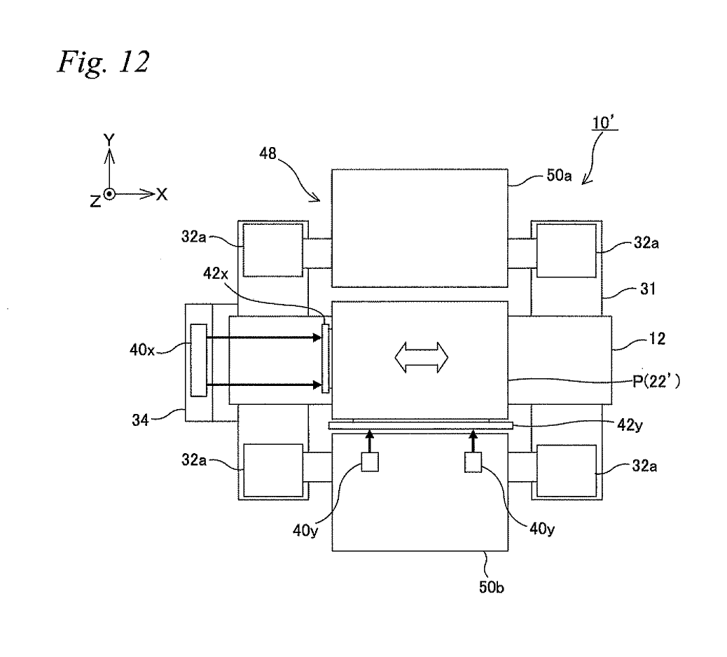

Next, a second embodiment is described with reference to FIGS. 12 to 17B. In this case, the same or similar reference signs are used for the same or equivalent components as/to those in the first embodiment described earlier and the description thereof is simplified or omitted.

FIG. 12 shows a schematic configuration of an exposure apparatus 10′ related to the present second embodiment, in a plan view. Exposure apparatus 10′ is a projection exposure apparatus of a scanning exposure type similar to exposure apparatus 10 described earlier, in which a mask and a substrate are each scanned relative to a projection optical system during exposure.

Exposure apparatus 10′ is different from exposure apparatus 10 related to the first embodiment described earlier mainly in that during carry-out of substrate P from a substrate holder 22′ and carry-in of substrate P onto substrate holder 22′, i.e., during the substrate exchange, carriage of substrate P by first carrier unit 50a and second carrier unit 50b is performed not via substrate tray 90.

As can be seen when comparing FIGS. 12 and 2, in exposure apparatus 10′, substrate holder 22′ is provided instead of substrate holder 22 described previously. Further, in exposure apparatus 10′ of first carrier unit 50a and second carrier unit 50b that configure substrate exchanging device 48, first carrier unit 50a is used exclusively for carry-out of a substrate from substrate holder 22′ and second carrier unit 50b is used exclusively for carry-in of a substrate onto substrate holder 22′. Consequently, in the description below, first carrier unit 50a and second carrier unit 50b are respectively referred to as a substrate carry-out device 50a and a substrate carry-in device 50b.

The configurations of the other parts of exposure apparatus 10′ are similar to those of exposure apparatus 10 described earlier.

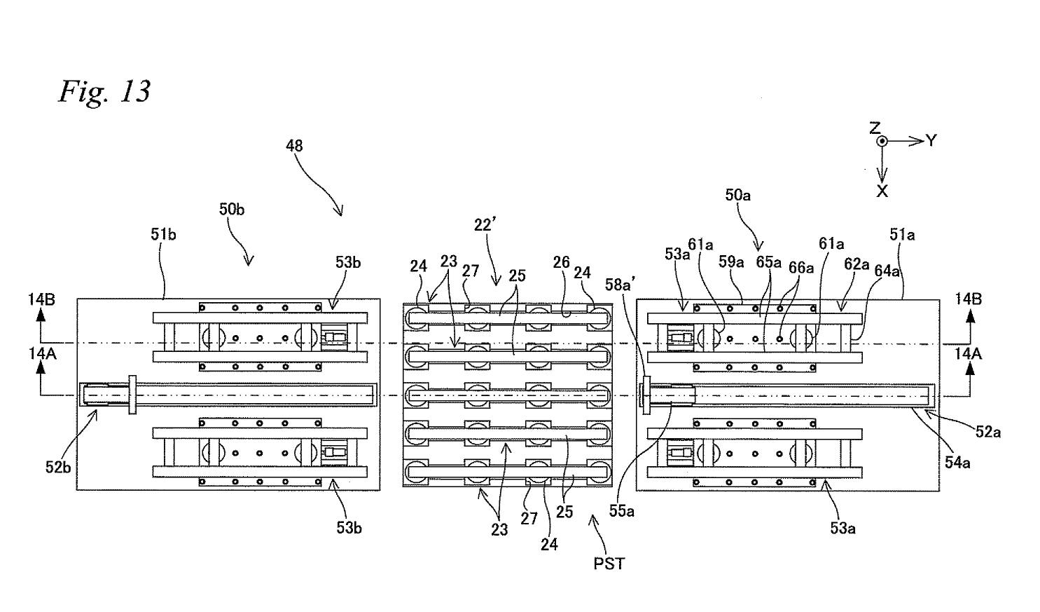

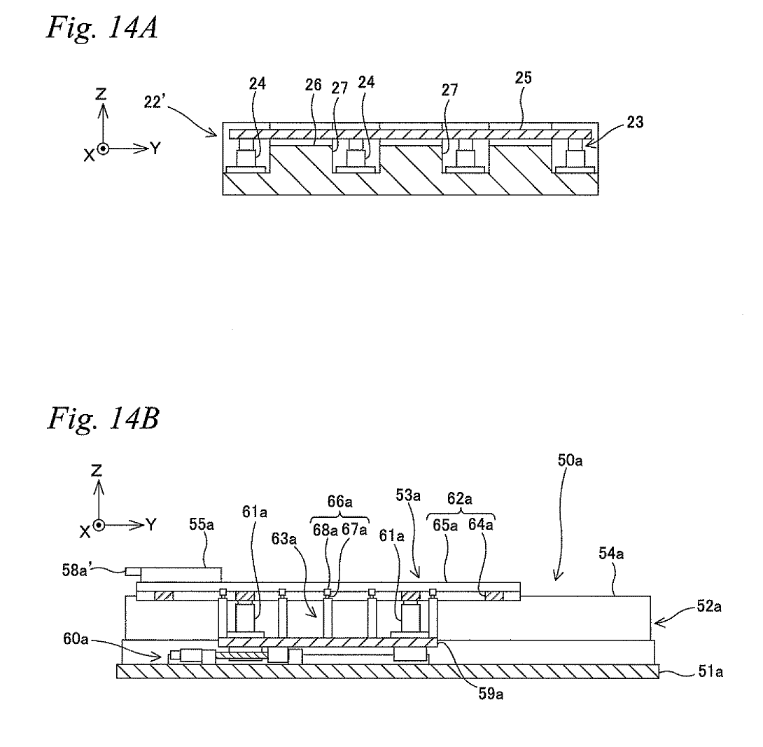

FIG. 13 shows a plan view (a view corresponding to FIG. 3 described earlier) of substrate holder 22′ of substrate stage device PST, substrate carry-out device 50a and substrate carry-in device 50b which exposure apparatus 10′ is equipped with. Note that FIG. 14A shows a cross-sectional view of substrate holder 22′ taken along a line 14A-14A shown in FIG. 13, and FIG. 14B shows a cross-sectional view of substrate carry-out device 50a taken along a line 14B-14B shown in FIG. 13.

As is obvious from FIGS. 13 and 14A, on the upper surface of substrate holder 22′, a plurality, e.g. five, of groove sections 26 extending in the Y-axis direction with a predetermined depth, which are similar to groove sections 26y described earlier, and a plurality of recessed sections 27 with a depth deeper than groove sections 26y are formed, but groove sections corresponding to groove sections 26x are not formed. Further, in substrate holder 22′, instead of air levitation units 23a and 23b described earlier, five air levitation units 23 that are configured similarly to air levitation units 23b are provided. More specifically, each of air levitation units 23 includes a plurality, e.g. four, of air cylinders 24 and air levitation device 25. At rod tips of, for example, four air cylinders 24 that air levitation unit 23 has, air levitation device 25 is installed over. The configurations of the other parts of substrate holder 22′ are similar to those of substrate holder 22 described earlier.

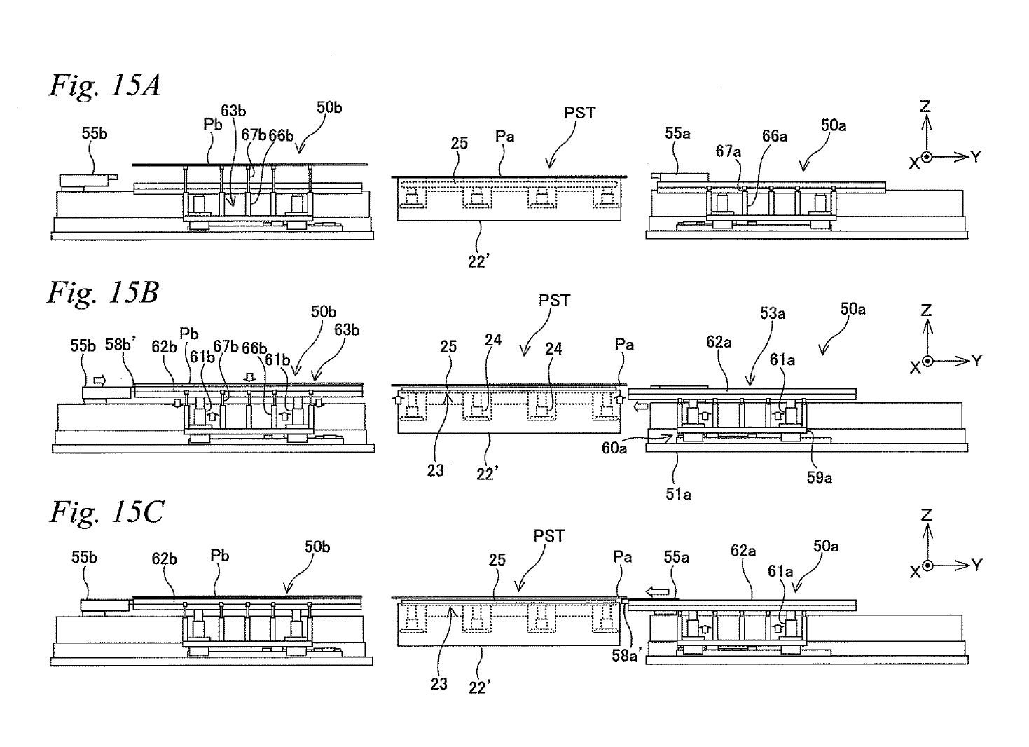

Further, as is obvious from FIGS. 13 and 14B, in substrate carry-out device 50a, instead of adsorption pad 58a described earlier, as a holding member, an adsorption pad 58a′ is arranged at the end on the −Y side (on the substrate stage device PST (substrate holder 22′) side) of mover section 55a. Although adsorption pad 58a′ is configured similar to adsorption pad 58, adsorption pad 58a′ holds the lower surface of substrate P (not illustrated in FIG. 13, see the drawings such as FIGS. 12 and 15C) by adsorption with the +Z side surface of adsorption pad 58a′. Incidentally, it is also possible that adsorption pad 58a′ holds the upper surface of substrate P by adsorption. Further, instead of adsorption pad 58′, a mechanical chuck that mechanically holds (grips) substrate P can be provided, as a holding section, at mover section 55a.

Further, in the present second embodiment, air levitation device 62a that each of the pair of air levitation units 53a has, provided in substrate carry-out device 50a, directly levitates substrate P not via a substrate tray. The configurations of the other parts of substrate carry-out device 50a are similar to those of the first substrate carrier device related to the first embodiment described previously.

While being placed bilaterally symmetric to substrate carry-out device 50a on the page surface of FIG. 13, substrate carry-in device 50b has substantially the same configuration as substrate carry-out device 50a, and therefore the detailed description thereof is omitted. In the description below, “a” of the reference signs that denote the respective members of substrate carry-out device 50a is replaced with “b” and the reference signs with “b” are used as reference signs that denote the respective members of substrate carry-in device 50b.

In exposure apparatus 10′, under control of the main controller that is not illustrated, loading of a mask onto the mask stage and carry-in (loading) of substrate P onto substrate holder 22′ by substrate carry-in device 50b (see FIG. 13) are performed. After that, the main controller executes alignment measurement using an alignment detection system that is not illustrated, and after the alignment measurement has been completed, an exposure operation is performed. Then, substrate P that has been exposed is carried out (unloaded) from substrate holder 22′ by substrate carry-out device 50a (see FIG. 13), and another substrate P is carried into (loaded onto) substrate holder 22′ by substrate carry-in device 50b. In other words, in exposure apparatus 10′, the exposure processing is consecutively performed to a plurality of substrates P by repeatedly performing the exchange of substrate P on substrate holder 22′.

Now, the exchange procedure of substrate P on substrate holder 22′ using substrate carry-out device 50a and substrate carry-in device 50b, in exposure apparatus 10′ related to the present second embodiment, is described with reference to FIGS. 15A to 17B. Note that FIGS. 15A to 17B are views used to explain the exchange procedure of substrate P, and show only substrate holder 22′ of substrate stage device PST. And, in order to facilitate the understanding, the description is made referring to a substrate after the exposure processing to which the exposure processing has been completed and is carried out from substrate holder 22′, as a substrate Pa, and referring to a substrate subject to exposure (to be exposed) that is newly mounted on substrate holder 22′, as a substrate Pb, in FIGS. 15A to 17B. The substrate exchange is performed under the control of the main controller that is not illustrated.

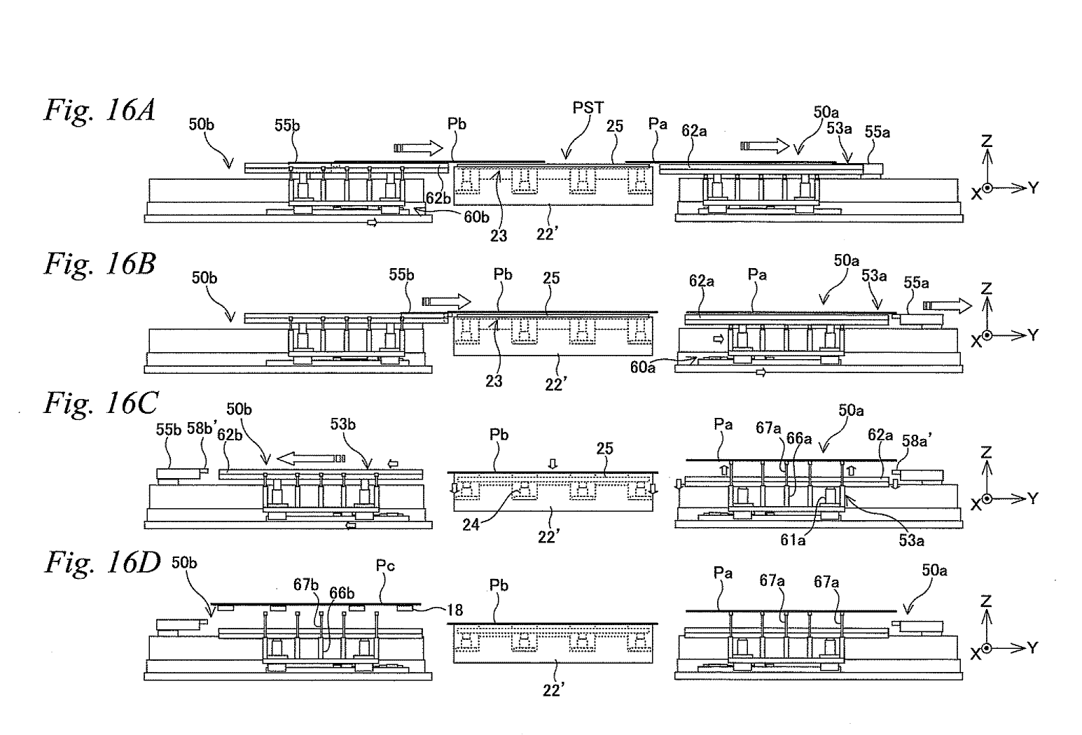

FIG. 15A shows substrate stage device PST immediately after the exposure processing with respect to substrate Pa has been completed. On substrate holder 22′, substrate Pa after exposure is mounted. Substrate holder 22′ is located at the substrate exchange position shown FIG. 12 (the location where substrate carry-in device 50b and substrate carry-out device 50a are the same in position in the X-axis direction). And, in substrate carry-in device 50b, the plurality of lift pins 67b are in a state located at the movement limit position on the +Z side (upper limit movement position) and substrate Pb to which the exposure processing is to be performed next is supported from below by the plurality of pins 67b. In the middle of performing the exposure processing of substrate Pa, substrate Pb is carried into exposure apparatus 10′ from the outside and is mounted on the plurality of lift pins 67b, by a predetermined robot 18 for substrate carriage (not illustrated in FIG. 15A, see FIG. 16D). And, mover section 55b is located at the movement limit position on the −Y side (the farthest position from substrate holder 22′). Meanwhile, in substrate carry-out device 50a, mover section 55a is located at a position that is slightly on the +Y side from the movement limit position on the −Y side (the closest position to substrate holder 22′). The plurality of lift pins 67a are in a state located at the movement limit position on the −Z side (lower limit movement position).

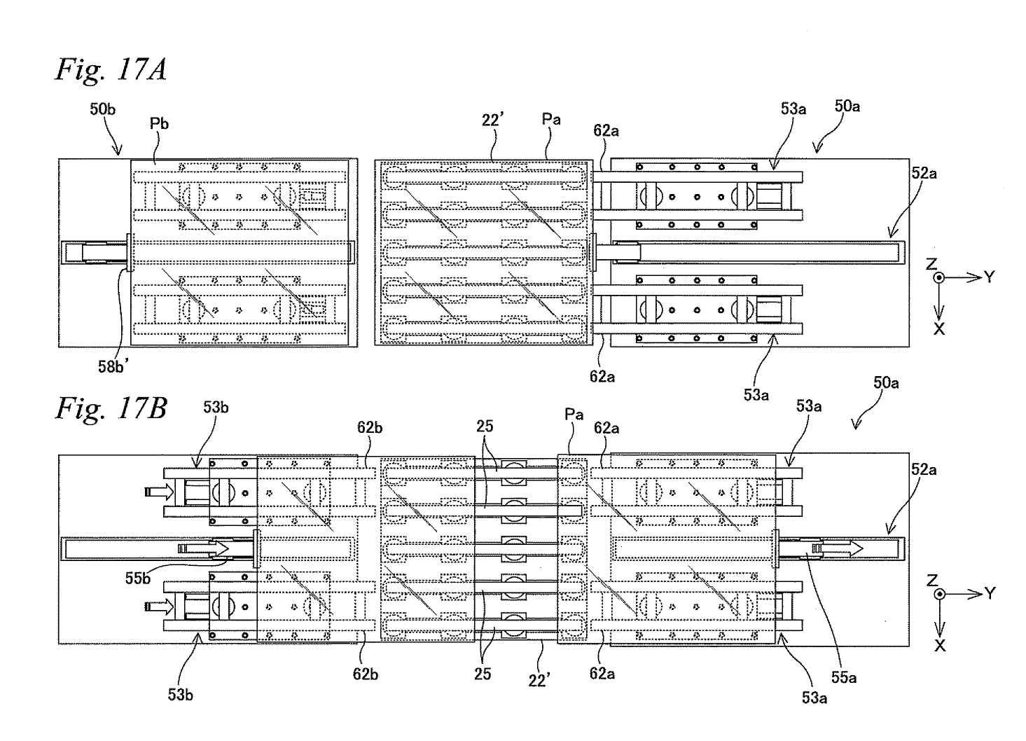

Subsequently, as shown in FIG. 15B, for carry-out of substrate Pa that has been exposed, the holding by adsorption of substrate Pa by substrate holder 22′ is released and air is supplied to the plurality of air cylinders 24 inside substrate holder 22′. Accordingly, the rod of each of the plurality of air cylinders 24 moves in the +Z direction, substrate Pa is supported in a noncontact manner from below by the plurality of air levitation devices 25 and is lifted in the +Z direction, and thereby the lower surface of substrate Pa separates from the upper surface of substrate holder 22′. Further, in substrate carry-out device 50a, each of a pair of air levitation units 53a (movable bases 59a) is driven to the −Y side by Y drive unit 60a, and the −Y side end of each of the pair of air levitation devices 62a protrudes to the −Y side further than base 51a (see FIG. 17A that is a plan view corresponding to FIG. 15B). Along with this operation, air is supplied to the pair of air cylinders 61a that each of the pair of air levitation units 53a has (a total of four air cylinders 61a), and air levitation devices 62a are driven to the +Z side.

Further, in substrate carry-in device 50b, air is supplied to the pair of air cylinders 61b that each of the pair of air levitation units 53b has (a total of four air cylinders 61b), and accordingly the rod of each of four air cylinders 61b moves in the +Z direction, and air levitation devices 62b move to the +Z side. The Z-position of the upper surface of each air levitation device 62b at this point roughly coincides with the Z-position of the upper surface of each air levitation device 25 that substrate holder 22′ has. Further, the plurality of lift pins 67b are driven in the −Z direction, and substrate Pb is supported in a noncontact manner from below by the pair of air levitation devices 62b. After substrate Pb is supported by the pair of air levitation devices 62b, the plurality of lift pins 67b are further driven to the −Z side, and thereby each of lift pins 67b separates from the lower surface of substrate Pb. Further, after mover section 55b is driven in the +Y direction and substrate Pb descends, adsorption pad 58b′ holds substrate Pb by adsorption (see FIG. 17A).

Next, as shown in FIG. 15C, mover section 55a of substrate carry-out device 50a is driven in the −Y direction, and adsorption pad 58a′ is inserted below the +Y side end of substrate Pa. After that, the pair of air levitation devices 62a are further driven in the +Z direction by four air cylinders 61a. Then, adsorption pad 58a′ holds substrate Pa by adsorption. The Z-position of the upper surface of each of air levitation devices 62a roughly coincides with the Z-position of the upper surface of each of air levitation devices 25 that substrate holder 22′ has.

After that, as shown in FIG. 16A, mover section 55a of substrate carry-out device 50a is driven in the +Y direction. On this operation, the pressurized gas is blown out from each of the pair of air levitation devices 62a of substrate carry-out device 50a and the plurality of air levitation devices 25 of substrate holder 22′. Accordingly, substrate Pa moves (slides) parallel to the horizontal plane, in a levitated state, from above the plurality of air levitation devices 25 of substrate holder 22′ to above the pair of air levitation devices 62a of substrate carry-out device 50a, thereby being delivered from substrate holder 22′ to substrate carry-out device 50a (see FIG. 17B that is a plan view corresponding to FIG. 16A). Further, in parallel with (in conjunction with) this carry-out operation of substrate Pa from substrate holder 22′, the pair of air levitation devices 62b of substrate carry-in device 50b are driven in the +Y direction by Y drive unit 60b, and the +Y side ends of the pair of air levitation devices 62b approach the −Y side end of substrate holder 22′. Further, in substrate carry-in device 50b, mover section 55b is driven in the +Y direction. On this operation, by the pressurized gas being blown out from the pair of air levitation devices 62b, substrate Pb moves (slides) parallel to the horizontal plane, in a levitated state, from above the pair of air levitation devices 62b of substrate carry-in device 50b to above the plurality of air levitation devices 25 of substrate holder 22′, thereby being delivered from substrate carry-in device 50b to the plurality of air levitation devices 25 of substrate holder 22′ (see FIG. 17B). Incidentally, while, in FIGS. 16A and 17B, the replacement (exchange) operation of the substrate on substrate holder 22′ is performed in a state where a predetermined interspace (gap) is formed between the −Y side end (the rear end in a carry-out direction) of substrate Pa and the +Y side end (the front end in a carry-in direction) of substrate Pb, this is not intended to be limiting, and it is also possible that the replacement of the substrate on substrate holder 22′ is performed in a state where substrate Pa and substrate Pb are in a closer state.

Subsequently, as shown in FIG. 16B, in substrate carry-out device 50a, mover section 55a is further driven in the +Y direction, and substrate Pa is completely moved out of substrate holder 22′ and mounted on substrate carry-out device 50a. Then, in accordance with this operation, the pair of air levitation devices 62a are driven in the Y direction by the pair of Y drive units 60a, respectively. Further, in parallel with the carry-out of substrate Pa from substrate holder 22′, mover section 55b is further driven in the +Y direction in substrate carry-in device 50b. Accordingly, substrate Pb is completely delivered from the pair of air levitation devices 62b to the plurality of air levitation devices 25 of substrate holder 22′.

Subsequently, as shown in FIG. 16C, in substrate carry-out device 50a, the holding by adsorption of substrate Pa by adsorption pad 58a′ is released. Further, air is supplied to the plurality of air cylinders 66a, and the plurality of lift pins 67a move in the +Z direction, so that substrate Pa is supported from below and lifted upward, and is separated from the pair of air levitation devices 62a. Further, in parallel with this operation, the rod of each of four air cylinders 61a is driven in the −Z direction, and the pair of air levitation devices 62a descend.

Meanwhile, in substrate carry-in device 50b, after the holding by adsorption of substrate Pb by adsorption pad 58b′ is released, mover section 55b and the pair of air levitation devices 62b are each driven in the −Y direction, and is returned to the respective initial positions shown in FIG. 15A. Further, in substrate holder 22′, the rod of each of the plurality of air cylinders 24 is driven to the −Z side, and substrate Pb descends. Accordingly, the lower surface of substrate Pb comes in contact with the upper surface of substrate holder 22′, and substrate holder 22′ holds substrate Pb by adsorption. Further, after the lower surface of substrate Pb comes in contact with the upper surface of substrate holder 22′ as well, the rods of the plurality of air cylinders 24 are further driven to the −Z side, and thereby the plurality of air levitation devices 25 separate from the lower surface of substrate Pb.

After that, as shown in FIG. 16D, in substrate carry-in device 50b, air is supplied to the plurality of air cylinders 66b, the plurality of lift pins 67b are driven in the +Z direction, and on the plurality of lift pins 67b, a new substrate Pc subject to exposure that has been carried from the outside by substrate carrying robot 18 is mounted. Further, in substrate carry-out device 50a, substrate Pa supported from below by the plurality of lift pins 67a is carried toward an external device (e.g. a coater/developer device) by a substrate carrying robot that is not illustrated. Afterwards, in exposure apparatus 10′, every time exposure of a substrate on substrate holder 22′ is performed, the substrate exchange operation shown in FIGS. 15A to 16D is repeated, and thereby the consecutive processing (exposure) is performed with respect to a plurality of substrates P.

As is described above, in exposure apparatus 10′ related to the present second embodiment, similarly to the first embodiment described above, the carry-in operation of substrate P to substrate holder 22′ and the carry-out operation of another substrate P from substrate holder 22′ are performed in parallel on substrate holder 22′, and therefore, the entire throughput in the case of consecutively performing the exposure processing with respect to a plurality of substrates can be improved.

Further, because substrate holder 22′, substrate carry-in device 50b and substrate carry-out device 50a are each provided with the air levitation units and move substrate P in a levitated state, substrate P can be moved at a high speed and with low generation of dust. Further, the rear surface of substrate P can be prevented from being damaged.

Further, since substrate P subject to carry-in and substrate P subject to carry-out are moved on the same plane, substrate exchanging device 48 related to the present second embodiment is effective also in the case where a space above substrate holder 22′ is small.

Further, since the plurality of air levitation devices 25 used to levitate substrate P can be housed inside substrate holder 22′, a particular configuration does not have to be employed for substrate holder 22′ in order to perform slide carriage of substrate P directly on the substrate mounting surface.

Further, since the pair of air levitation devices 62b are made to approach substrate holder 22′ when substrate P is delivered from substrate carry-in device 50b to substrate holder 22′, the bending of substrate P caused by the self weight can be restrained and the delivery of substrate P can smoothly be performed. Similarly, also when substrate P is carried out from substrate holder 22′ to substrate carry-out device 50a, the pair of air levitation devices 62a of substrate carry-out device 50a are made to approach substrate holder 22′, and therefore, the bending of substrate P can be restrained.

Further, because substrate P is directly carried, the control can be made without difficulty, compared with, for example, the case where substrate P is carried being mounted on a tray member or the like for carriage.

Incidentally, in the second embodiment above, it is also possible that the exchange of substrate P mounted on substrate holder 22′ is repeatedly performed while the functions as a substrate carry-out device and a substrate carry-in device are alternately interchanged between first carrier unit 50a used exclusively for substrate carry-out and second carrier unit 50b used exclusively for substrate carry-in, which is similar to the first embodiment described earlier. On the contrary, in the first embodiment described earlier, it is also possible that one of first carrier unit 50a and second carrier unit 50b is used exclusively for substrate carry-out and the other is used exclusively for substrate carry-in.

Further, although the detailed description is omitted, modified examples similar to the first to third modified examples of the first embodiment described above can be employed also for the second embodiment above, and the equivalent effect can be obtained.

Further, also in exposure apparatus 10′ of the second embodiment above, when substrate P is delivered from substrate carry-in device 50b to substrate holder 22′, substrate carry-in device 50b as a whole (i.e. including base 51b) may be made to approach substrate holder 22′ as far as air levitation devices 62b and substrate holder 22′ can be made to approach each other. Further, also during the carry-out of substrate P from substrate holder 22′, similarly, substrate carry-out device 50a as a whole may be made to approach substrate holder 22′. Further, while, in the second embodiment above, the delivery of the substrate with respect to an external carrier device that is not illustrated is performed using the plurality of lift pins, the delivery of the substrate can be performed directly between the external carrier device and air levitation devices 62a and 62b described above without using the lift pins.

Further, while, in the second embodiment above, substrate carry-out device 50a and substrate carry-in device 50b respectively have traveling unit 52a and traveling unit 52b that each travel in the Y-axis direction holding the center portion of substrate P in the X-axis direction, the configuration of the traveling unit used to slide substrate P along the horizontal plane is not limited thereto, and for example, two positions, which spaced apart in the X-axis direction, of the end of substrate P can be held. In this case, the rotation of substrate P in the θz direction can be reliably restrained. Further, it is also possible that two traveling units are provided that respectively hold two positions, which are different from each other, of substrate P and the position of substrate P in the θz direction is positively controlled by controlling the two traveling units independently (in such a case, substrate P is held so as not to be restricted in the θz direction). In this case, especially during the substrate carry-in, substrate P can be delivered onto substrate holder 22′ with the respective sides being parallel to the X-axis and the Y-axis (the measurement axes of the interferometer system).

Incidentally, while, in the first and the second embodiments above, first carrier unit 50a and second carrier unit 50b are placed in a row in the Y direction during the substrate exchange, the carrier units do not necessarily have to be placed in a row. For example, it is also possible that first carrier unit 50a and second carrier unit 50b are respectively placed in directions that form an angle of 90 degrees with the substrate holder (22 or 22′) serving as a reference. Further, the transport direction of the substrate during the exchange is not limited to the X or the Y direction, and can be a direction intersecting the X-axis and the Y-axis.

Further, in the first and the second embodiments above, at least a part of at least one of first carrier unit 50a and second carrier unit 50b (port sections) does not necessarily have to be arranged in the exposure apparatus, but can be arranged at the coater/developer device or an interface section between the coater/developer device and the exposure apparatus.

Incidentally, in the first and the second embodiments above, the illumination light can be ultraviolet light, such as ArF excimer laser light (with a wavelength of 193 nm) and KrF excimer laser light (with a wavelength of 248 nm), or vacuum ultraviolet light such as F₂ laser light (with a wavelength of 157 nm). Further, as the illumination light, a harmonic wave, which is obtained by amplifying a single-wavelength laser light in the infrared or visible range emitted by a DFB semiconductor laser or fiber laser with a fiber amplifier doped with, for example, erbium (or both erbium and ytteribium), and by converting the wavelength into ultraviolet light using a nonlinear optical crystal, can also be used. Further, solid state laser (with a wavelength of 355 nm, 266 nm) or the like can also be used.

Further, while, in each of the embodiments above, the case has been described where projection optical system PL is the projection optical system by a multi-lens method that is equipped with a plurality of optical systems, the number of the projection optical systems is not limited thereto, but there should be one or more projection optical systems. Further, the projection optical system is not limited to the projection optical system by a multi-lens method, but can be a projection optical system using, for example, a large mirror of the Offner type, or the like.

Further, while the case has been described where the projection optical system whose projection magnification is equal magnification is used as projection optical system PL in each of the embodiments above, this is not intended to be limiting, and the projection optical system can be either of a magnifying system or a reduction system.

Further, in each of the embodiments above, a light transmissive type mask is used, which is obtained by forming a predetermined light-shielding pattern (or a phase pattern or a light-attenuation pattern) on a light transmissive mask substrate. Instead of this mask, however, as disclosed in, for example, U.S. Pat. No. 6,778,257, an electron mask (a variable shaped mask) on which a light-transmitting pattern, a reflection pattern, or an emission pattern is formed according to electronic data of the pattern that is to be exposed, for example, a variable shaped mask that uses a DMD (Digital Micromirror Device) that is a type of a non-emission type image display element (which is also called a spatial light modulator) can also be used.

Further, the application of the exposure apparatus is not limited to the exposure apparatus for liquid crystal display elements in which a liquid crystal display element pattern is transferred onto a rectangular glass plate, but each of the embodiments above can also be widely applied, for example, to an exposure apparatus for manufacturing semiconductors, and an exposure apparatus for producing thin-film magnetic heads, micromachines, DNA chips, and the like. Further, each of the embodiments above can also be applied to an exposure apparatus that transfers a circuit pattern onto a glass substrate, a silicon wafer or the like not only when producing microdevices such as semiconductor devices, but also when producing a mask or a reticle used in an exposure apparatus such as an optical exposure apparatus, an EUV exposure apparatus, an X-ray exposure apparatus, and an electron beam exposure apparatus.

Incidentally, an object that is subject to exposure is not limited to a glass plate, but for example, can be another object such as a wafer, a ceramic substrate, a film member or a mask blank. Further, in the case where an exposure subject is a substrate for flat-panel display, the thickness of the substrate is not limited in particular, and for example, a film like member (a sheet like member having flexibility) is also included.

Incidentally, the exposure apparatus related to each of the embodiments above is especially effective for the case where a substrate with an outer diameter not less than 500 mm is an exposure subject.

Incidentally, the disclosures of all publications, the PCT International Publications, the U.S. Patent Application Publications and the U.S. Patents related to exposure apparatuses and the like that are cited in the description so far are each incorporated herein by reference.

### Device Manufacturing Method

A manufacturing method of a microdevice that uses the exposure apparatus related to each of the embodiments above in a lithography process is described next. In the exposure apparatus related to each of the embodiments above, a liquid crystal display element as a microdevice can be obtained by forming a predetermined pattern (such as a circuit pattern and an electrode pattern) on a substrate (a glass substrate).

Pattern Forming Process

First of all, a so-called optical lithography process in which a pattern image is formed on a photosensitive substrate (such as a glass substrate coated with a resist) is executed using the exposure apparatus related to each of the embodiments above described above. In this optical lithography process, a predetermined pattern that includes many electrodes and the like is formed on the photosensitive substrate. After that, the exposed substrate undergoes the respective processes such as a development process, an etching process and a resist removing process, and thereby the predetermined pattern is formed on the substrate.

Color Filter Forming Process

Next, a color filter in which many sets of three dots corresponding to R (Red), G (Green) and B (blue) are disposed in a matrix shape, or a color filter in which a plurality of sets of filters of three stripes of R, G and B are disposed in horizontal scanning line directions is formed.

Cell Assembling Process

Next, a liquid crystal panel (a liquid crystal cell) is assembled using the substrate having the predetermined pattern obtained in the pattern forming process, the color filter obtained in the color filter forming process, and the like. For example, a liquid crystal panel (a liquid crystal cell) is manufacture by injecting liquid crystal between the substrate having the predetermined pattern obtained in the pattern forming process and the color filter obtained in the color filter forming process.

Module Assembling Process

After that, a liquid crystal display element is completed by attaching respective components such as an electric circuit that causes a display operation of the assembled liquid crystal panel (liquid crystal cell) to be performed, and a backlight.

In this case, since exposure of the substrate is performed with high throughput and high precision using the exposure apparatus related to each of the embodiments above in the pattern forming process, the productivity of microdevices (liquid crystal display elements) can be improved as a consequence.

While the above-described embodiments of the present invention are the presently preferred embodiments thereof, those skilled in the art of lithography systems will readily recognize that numerous additions, modifications, and substitutions may be made to the above-described embodiments without departing from the spirit and scope thereof. It is intended that all such modifications, additions, and substitutions fall within the scope of the present invention, which is best defined by the claims appended below.

What is claimed is:

1. An exposure apparatus that consecutively exposes a plurality of objects with an energy beam, the apparatus comprising:
a holding device that holds an object during exposure processing with the energy beam, and is movable in at least one direction within a predetermined plane parallel to a surface of the object with respect to the energy beam;
a first carrier device that carries out the object on the holding device, from the holding device; and
a second carrier device that carries in another object onto the holding device in a state where a part of the object subject to carry-out is located on the holding device.

2. The exposure apparatus according to claim 1, wherein
the first carrier device moves the object subject to carry-out along a first path in a first direction parallel to the predetermined plane, and
the second carrier device moves the object subject to carry-in along a second path located on an extended line of the first path.

3. The exposure apparatus according to claim 2, wherein
the holding device is movable with predetermined strokes in at least a second direction orthogonal to the first direction within the predetermined plane.

4. The exposure apparatus according to claim 1, wherein
the second carrier device carries out the object that has been carried in onto the holding device, from the holding device, and
the first carrier device carries in yet another object onto the holding device in a state where a part of the object that is carried out from the holding device by the second carrier device is located on the holding device.

5. The exposure apparatus according to claim 1, wherein
the first carrier device and the second carrier device carry the object together with a first support member and a second support member, respectively, each of the first support member and the second support member supporting the object from below.

6. The exposure apparatus according to claim 5, wherein
the holding device has a first guide member that sets a movement plane used on movement of the first support member and the second support member, and
the first guide member is housed in the holding device when the object is held on a holding surface of the holding device.

7. The exposure apparatus according to claim 6, wherein
the first guide member includes a levitation device that levitates the first support member and the second support member.

8. The exposure apparatus according to claim 5, wherein
the first carrier device has a second guide member that sets a movement plane used on movement of the first support member,
the second carrier device has a third guide member that sets a movement plane used on movement of the second support member, and
the second guide member and the third guide member are each movable in an approaching direction and a separating direction to/from the holding device.

9. The exposure apparatus according to claim 8, wherein
the second guide member includes a levitation device that levitates the first support member, and the third guide member includes a levitation device that levitates the second support member.

10. The exposure apparatus according to claim 1, wherein
the holding device has a first movement plane setting member that sets a movement plane used on carry-in and carry-out of the object, and
the first movement plane setting member is housed in the holding device when the object is held on a holding surface of the holding device.

11. The exposure apparatus according to claim 10, wherein
the first movement plane setting member includes a levitation device that levitates the object during carry-in and carry-out of the object.

12. The exposure apparatus according to claim 1, wherein
the first carrier device has a second movement plane setting member that sets a movement plane used when the object subject to carry-out is carried out, and
the second movement plane setting member is movable in an approaching direction and a separating direction to/from the holding device.

13. The exposure apparatus according to claim 12, wherein
the second movement plane setting member includes a levitation device that levitates the object subject to carry-out.

14. The exposure apparatus according to claim 1, wherein
the second carrier device has a third movement plane setting member that sets a movement plane used when the object subject to carry-in is carried in, and
the third movement plane setting member is movable in an approaching direction and a separating direction to/from the holding device.

15. The exposure apparatus according to claim 14, wherein
the third movement plane setting member includes a levitation device that levitates the object subject to carry-in.

16. The exposure apparatus according to claim 1, wherein
each of the first carrier device and the second carrier device as a whole is movable in an approaching direction and a separating direction to/from the holding device.

17. A device manufacturing method, comprising:
exposing the object using the exposure apparatus according to claim 1; and
developing the object that has been exposed.

18. The device manufacturing method according to claim 17, wherein
the object is a substrate whose size is not less than 500 mm.

19. A flat-panel display manufacturing method, comprising:
exposing a substrate used for a flat-panel display as the object, using the exposure apparatus according to claim 1; and
developing the substrate that has been exposed.

20. An exchange method of an object to exchange an object held on a holding device that is movable in at least one direction within a predetermined plane parallel to a surface of the object, for another object, the method comprising:
carrying out the object on the holding device, from the holding device; and
carrying in another object onto the holding device in a state where a part of the object is located on the holding device.

21. The exchange method of the object according to claim 20, wherein
in the carrying out the object, the object subject to carry-out is moved along a first path in a first direction parallel to the predetermined plane, and
in the carrying in the object, the object subject to carry-in is moved along a second path located on an extended line of the first path.

22. The exchange method of the object according to claim 20, wherein
in the carrying out the object, the object subject to carry-out is carried together with a first support member that supports the object from below, and
in the carrying in the object, the object subject to carry-in is carried together with a second support member that supports the object from below.

23. The exchange method of the object according to claim 22, wherein
during carry-out and carry-in of the object, guide members that respectively set a movement plane of the first support member and a movement plane of the second support member are each made to approach the holding device.

24. The exchange method of the object according to claim 20, wherein
when the first support member and the second support member move on the holding device, the first support member and the second support member are levitated.

25. The exchange method of the object according to claim 20, wherein
in the carrying out the object, the object is levitated and carried out from the holding device.

26. The exchange method of the object according to claim 20, wherein
in the carrying in the object, the object is levitated and carried in to the holding device.

27. The exchange method of the object according to claim 20, wherein
in the carrying out the object, a movement plane setting member that sets a movement plane of the object subject to carry-out is made to approach the holding device.

28. The exchange method of the object according to claim 20, wherein
in the carrying in the object, a movement plane setting member that sets a movement plane of the object subject to carry-in is made to approach the holding device.

29. An exposure method of consecutively exposing a plurality of objects, the method comprising:
exchanging the object held on a holding device for another one of the objects, with the exchange method of the object according to claim 20; and
exposing the object after exchange on the holding device with an energy beam.

30. A device manufacturing method, comprising:
exposing the object with the exposure method according to claim 29; and
developing the object that has been exposed.

31. A flat-panel display manufacturing method, comprising:
exposing a substrate used for a flat-panel display as the object, with the exposure method according to claim 29; and
developing the substrate that has been exposed.

32. An exposure method of consecutively exposing a plurality of objects, the method comprising:
setting a first path and a second path in one direction parallel to a predetermined plane, respectively on one side and the other side of an object exchange position, carrying out an object after exposure from a holding device located at the exchange position along one of the first path and the second path, and carrying in an object before exposure onto the holding device located at the exchange position along the other of the first path and the second path; and
exposing the object before exposure on the holding device with an energy beam.

33. The exposure method according to claim 32, wherein
carry-out of the object after exposure from the holding device located at the exchange position and carry-in of the object before exposure onto the holding device are performed at least partly in parallel.

34. The exposure method according to claim 32, wherein
the object after exposure is carried out from the holding device, together with a first support member that supports the object from below, and the object before exposure is carried in onto the holding device, together with a second support member that supports the object from below.

35. A device manufacturing method, comprising:
exposing the object with the exposure method according to claim 32; and
developing the object that has been exposed.

36. The device manufacturing method according to claim 35, wherein
the object is a substrate whose size is not less than 500 mm.

37. A flat-panel display manufacturing method, comprising:
exposing a substrate used for a flat-panel display as the object, with the exposure method according to claim 32; and
developing the substrate that has been exposed.
